(19) United States
(12) Patent Application Publication
(10) Pub. No.: US 2026/0363116 A1
(43) Pub. Date: Nov. 12, 2026

(54) SEMICONDUCTOR PACKAGE

(71) Applicant: Murata Manufacturing Co., Ltd., Kyoto-fu (JP)

(72) Inventors: Yoshimasa YOSHIOKA, Nagaokakyo-shi (JP); Takuo WAKAOKA, Nagaokakyo-shi (JP); Ryo KASAI, Nagaokakyo-shi (JP)

(73) Assignee: Murata Manufacturing Co., Ltd., Kyoto-fu (JP)

(21) Appl. No.: 19/721,807

(22) Filed: Jun. 26, 2026

Related U.S. Application Data
(63) Continuation of application No. PCT/JP2024/028846, filed on Aug. 13, 2024.

(30) Foreign Application Priority Data
Dec. 28, 2023 (JP) 2023-222443

(51) Int. Cl. H10W 70/652

(52) U.S. Cl. CPC H10W 70/652

(57) ABSTRACT

A semiconductor package includes a substrate having a first main surface and a semiconductor device mounted on the first main surface. The substrate includes a first wiring layer extending parallel to the first main surface, a first interlayer insulating layer at a position different from a position of the first wiring layer in a direction orthogonal to the first main surface, and a first functional layer having a plate shape, inside the first interlayer insulating layer, and extending parallel to the first main surface. When viewed in the direction orthogonal to the first main surface in a see-through manner, the first functional layer overlaps the first wiring layer without another wiring part interposed therebetween. A volume of the first functional layer is 0.5 times or less that of the substrate. A relative permeability of the first functional layer is at least twice that of the first interlayer insulating layer.

### CROSS-REFERENCE TO RELATED APPLICATIONS

This application claims benefit of priority to International Patent Application No. PCT/JP2024/028846, filed Aug. 13, 2024, and to Japanese Patent Application No. 2023-222443, filed Dec. 28, 2023, the entire contents of each are incorporated herein by reference.

### TECHNICAL FIELD

The present disclosure relates to semiconductor packages.

### BACKGROUND ART

The electronic component described in Japanese Unexamined Patent Application Publication No. 2020-178007 includes a core substrate. The core substrate has openings extending through the core substrate. The inside of each opening is filled with a magnetic resin. In addition, the magnetic resin has a through hole. A through-hole conductor is located inside the through hole. The electronic component includes insulating layers and conductor layers. The insulating layers are located on main surfaces of the core substrate. The conductor layers are located on surfaces of the insulating layers. The conductor layers, together with the above-mentioned through-hole conductors, form inductors.

### SUMMARY

In electronic components as described in Japanese Unexamined Patent Application Publication No. 2020-178007, the volume of the magnetic resin affects characteristics of the inductors formed by the conductor layers and the through-hole conductors. Hence, when the thickness of the core substrate is reduced, the volume of the magnetic resin is reduced, and characteristics required for the inductors are sometimes not satisfied. That is, in electronic components as described in Japanese Unexamined Patent Application Publication No. 2020-178007, it is difficult to achieve a reduced thickness while maintaining characteristics required for the inductors. Here, an example in which part of the core substrate functions as inductors is described above, but when part of the core substrate functions as elements such as capacitors, it is also difficult to achieve a reduced thickness while maintaining required characteristics for the same reason.

Therefore, a semiconductor package according to the present disclosure includes a substrate having a first main surface; and a semiconductor device mounted on the first main surface. The substrate includes a first wiring layer extending parallel to the first main surface, a first interlayer insulating layer located at a position different from a position of the first wiring layer in a direction orthogonal to the first main surface, and a first functional layer having a plate shape, located inside the first interlayer insulating layer, and extending parallel to the first main surface. When viewed in the direction orthogonal to the first main surface in a see-through manner, the first functional layer overlaps the first wiring layer without another wiring part interposed therebetween. Also, a volume of the first functional layer is 0.5 times or less a volume of the substrate, and a relative permeability of the first functional layer is at least twice a relative permeability of the first interlayer insulating layer.

In addition, a semiconductor package according to the present disclosure includes a substrate having a first main surface; and a semiconductor device mounted on the first main surface. The substrate includes a first wiring layer extending parallel to the first main surface, a second wiring layer located at a position different from a position of the first wiring layer in a direction orthogonal to the first main surface and extending parallel to the first main surface, a first interlayer insulating layer located between the first wiring layer and the second wiring layer, and a first functional layer having a plate shape, located inside the first interlayer insulating layer, and extending parallel to the first main surface. When viewed in the direction orthogonal to the first main surface in a see-through manner, the first functional layer overlaps the first wiring layer and the second wiring layer without another wiring part interposed therebetween. A volume of the first functional layer is 0.5 times or less a volume of the substrate, and a relative permittivity of the first functional layer is at least twice a relative permittivity of the first interlayer insulating layer.

The above configurations achieve a reduction in the thickness of the substrate while enabling part of the substrate to function as an electronic component having desired characteristics.

### BRIEF DESCRIPTION OF THE DRAWINGS

FIG. 1 is a schematic configuration diagram of a semiconductor package of a first embodiment;

FIG. 2 is an enlarged plan view of first inductor wiring lines, second inductor wiring lines, and their vicinity in the semiconductor package of the first embodiment, viewed in a see-through manner;

FIG. 3 is an explanatory diagram of a method of manufacturing the semiconductor package of the first embodiment;

FIG. 4 is an explanatory diagram of the method of manufacturing the semiconductor package of the first embodiment;

FIG. 5 is an explanatory diagram of the method of manufacturing the semiconductor package of the first embodiment;

FIG. 6 is an explanatory diagram of the method of manufacturing the semiconductor package of the first embodiment;

FIG. 7 is an explanatory diagram of the method of manufacturing the semiconductor package of the first embodiment;

FIG. 8 is an explanatory diagram of the method of manufacturing the semiconductor package of the first embodiment;

FIG. 9 is an explanatory diagram of the method of manufacturing the semiconductor package of the first embodiment;

FIG. 10 is an explanatory diagram of the method of manufacturing the semiconductor package of the first embodiment;

FIG. 11 is an explanatory diagram of the method of manufacturing the semiconductor package of the first embodiment;

FIG. 12 is an explanatory diagram of the method of manufacturing the semiconductor package of the first embodiment;

FIG. 13 is an explanatory diagram of the method of manufacturing the semiconductor package of the first embodiment;

FIG. 14 is an explanatory diagram of the method of manufacturing the semiconductor package of the first embodiment;

FIG. 15 is an explanatory diagram of the method of manufacturing the semiconductor package of the first embodiment;

FIG. 16 is a schematic configuration diagram of a semiconductor package of a second embodiment;

FIG. 17 is an enlarged plan view of first electrodes, a second electrode, and their vicinity in the semiconductor package of the second embodiment, viewed in a see-through manner;

FIG. 18 is a schematic configuration diagram of a semiconductor package of a modification;

FIG. 19 is a schematic configuration diagram of a semiconductor package of a modification;

FIG. 20 is a schematic configuration diagram of a semiconductor package of a modification;

FIG. 21 is a plan view of first inductor wiring lines, second inductor wiring lines, and their vicinity in the semiconductor package of the modification, viewed in a see-through manner;

FIG. 22 is a schematic configuration diagram of a semiconductor package of a modification; and

FIG. 23 is a schematic configuration diagram of a semiconductor package of a modification.

### DETAILED DESCRIPTION

Hereinafter, an embodiment of a semiconductor package will be described with reference to the drawings. In the drawings, components may be illustrated in an enlarged manner to facilitate understanding. The dimensional ratios of components may differ from the actual ones or from those in other drawings. In the following, some members are denoted as first, second, and so on. These are merely for convenience and do not indicate any priority of the members. Interpretation with ordinal numbers, such as first and second, interchanged is allowed.

### First Embodiment

### Overall Configuration

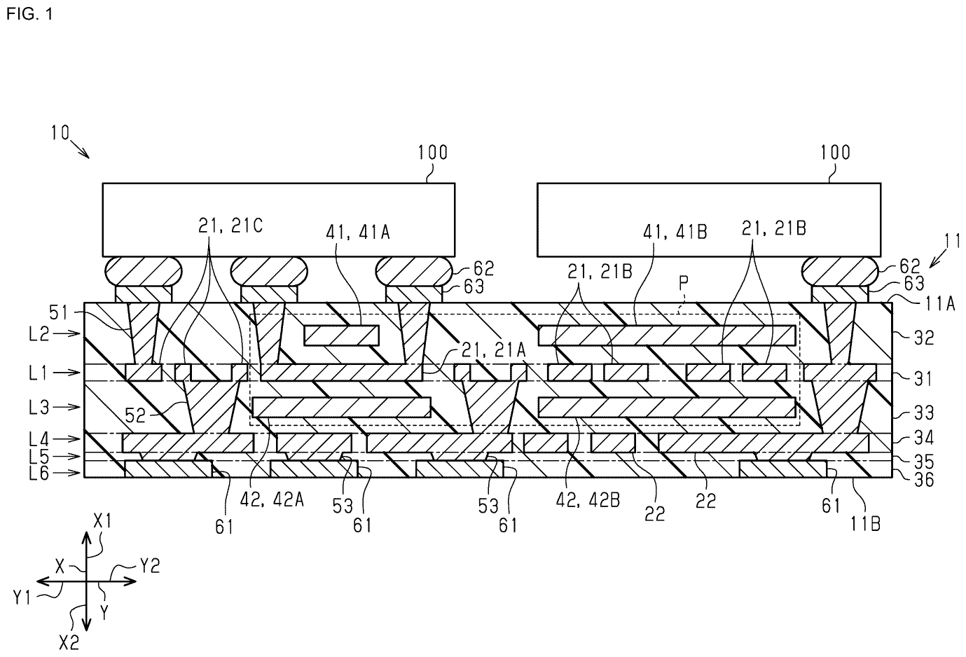

As illustrated in FIG. 1, a semiconductor package 10 includes a substrate 11 having a first main surface 11A and a second main surface 11B. The outer shape of the substrate 11 is, as a whole, a substantially rectangular parallelepiped. The first main surface 11A is one of the outer surfaces of the substrate 11 having the largest area. When viewed in a direction orthogonal to the first main surface 11A, the first main surface 11A has a rectangular shape. The second main surface 11B, among the outer surfaces of the substrate 11, is a surface parallel to the first main surface 11A. When viewed in a direction orthogonal to the second main surface 11B, the shape of the second main surface 11B is the same as the shape of the first main surface 11A.

In the following description, an axis orthogonal to the first main surface 11A is defined as a first axis X. An axis parallel to one of the sides of the first main surface 11A is defined as a second axis Y. An axis orthogonal to both the first axis X and the second axis Y is defined as a third axis Z. A specific direction of the directions along the first axis X is defined as a first positive direction X1, and the direction opposite to the first positive direction X1 is defined as a first negative direction X2. In the present embodiment, the first positive direction X1 corresponds to the direction that the first main surface 11A faces. A specific direction of the directions along the second axis Y is defined as a second positive direction Y1, and the direction opposite to the second positive direction Y1 is defined as a second negative direction Y2. A specific direction of the directions along the third axis Z is defined as a third positive direction Z1, and the direction opposite to the third positive direction Z1 is defined as a third negative direction Z2.

The substrate 11 includes a first layer L1, a second layer L2, a third layer L3, a fourth layer L4, a fifth layer L5, and a sixth layer L6. When viewed in a direction along the first axis X in a see-through manner, outer shapes of the first layer L1 to the sixth layer L6 are each rectangular. The layers of the substrate 11 are arranged from the first positive direction X1 side toward the first negative direction X2 side in the order of the second layer L2, the first layer L1, the third layer L3, the fourth layer L4, the fifth layer L5, and the sixth layer L6.

The first layer L1 is a layer at the second position from the first positive direction X1 side among the layers of the substrate 11. The first layer L1 includes a first wiring layer 21 and a first insulating layer 31. The material of the first wiring layer 21 is conductive. The material of the first wiring layer 21 contains, for example, at least one of Cu, Ag, Au, Ni, and Al. For example, the material of the first wiring layer 21 may be an alloy containing two or more of Cu, Ag, Au, Ni, and Al.

The first wiring layer 21 extends parallel to the first main surface 11A. In the present embodiment, the first wiring layer 21 includes a plurality of first inductor wiring lines 21A and a plurality of second inductor wiring lines 21B that are not coupled to each other within the first layer L1 in which the first wiring layer 21 is located. The shapes of the first inductor wiring lines 21A and the second inductor wiring lines 21B will be described later.

In addition, the first wiring layer 21 includes, in the layer in which the first wiring layer 21 is located, other wiring lines 21C as wiring lines different from the first inductor wiring lines 21A and the second inductor wiring lines 21B. The other wiring lines 21C extend in specified wiring patterns in the first layer L1. The other wiring lines 21C may be coupled to the first inductor wiring lines 21A and the second inductor wiring lines 21B, but need not be coupled thereto. In FIG. 1, only some of the other wiring lines 21C are denoted by reference signs.

The first insulating layer 31 is located in the portion of the first layer L1 other than the first wiring layer 21. The material of the first insulating layer 31 is an organic resin containing an inorganic filler. In the present embodiment, the inorganic filler is a silica filler. The inorganic filler is not limited to a silica filler and may be, for example, a glass filler. In the present embodiment, the organic resin is an epoxy resin. The organic resin is not limited to an epoxy-based resin and may be a polyimide-based resin, a liquid crystal polymer-based resin, an acrylic-based resin, a phenol-based resin, or a combination of some of these.

The second layer L2 is laminated on a surface of the first layer L1 on the first positive direction X1 side. That is, the second layer L2 is the outermost layer on the first positive direction X1 side in the substrate 11. A surface of the second layer L2 on the first positive direction X1 side is the first main surface 11A. The second layer L2 includes a first functional layer 41, a first interlayer insulating layer 32, and a plurality of first vias 51.

The first functional layer 41 extends parallel to the first main surface 11A. The first functional layer 41 includes flat-plate-shaped portions. The maximum dimension of the first functional layer 41 in the direction along the first axis X is smaller than the maximum dimension of the second layer L2 in the direction along the first axis X. The first functional layer 41 is not in contact with the first layer L1. In addition, the first functional layer 41 is not exposed at the first main surface 11A. In other words, the first functional layer 41 is embedded in the second layer L2. In the present embodiment, the first functional layer 41 includes a first functional portion 41A and a second functional portion 41B that are not coupled to each other within the second layer L2 in which the first functional layer 41 is located.

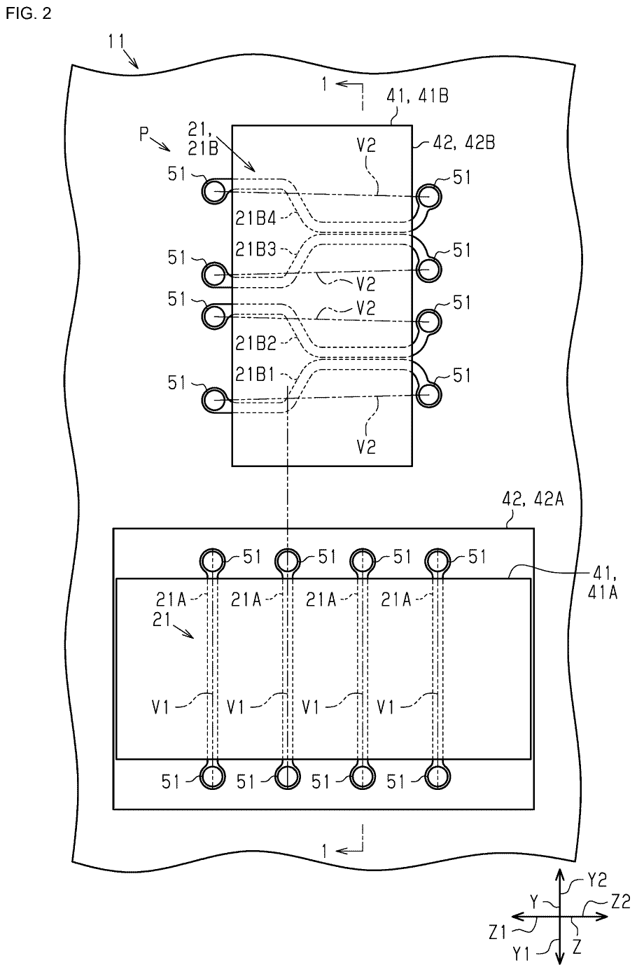

As illustrated in FIG. 2, when viewed in the direction along the first axis X in a see-through manner, the first functional portion 41A has a rectangular shape elongated in a direction along the third axis Z. That is, the first functional portion 41A has a rectangular shape having two sides parallel to the second axis Y and two sides parallel to the third axis Z. The material of the first functional portion 41A is an organic resin containing magnetic powder. In this embodiment, the magnetic powder is FeSiCr-based metal powder. The magnetic powder is not limited to FeSiCr-based metal powder and may be, for example, FeSi-based metal powder, FeAl-based metal powder, Fe-based metal powder, or a combination of some of these. As the first functional portion 41A, a cobalt-based alloy, such as a cobalt-zirconium-tantalum alloy, formed by sputtering may be employed. In this embodiment, the organic resin is an epoxy resin. The organic resin is not limited to an epoxy-based resin and may be a polyimide-based resin, a liquid crystal polymer-based resin, an acrylic-based resin, a phenol-based resin, or a combination of some of these. In the organic resin, an inorganic filler may be mixed in addition to the above materials. In the present embodiment, the first functional portion 41A has a magnetic powder content of 60 vol % or more. In the present embodiment, the first functional portion 41A does not have magnetic anisotropy. The magnetic powder contained in the first functional portion 41A is FeSiCr-based metal powder and is composed of spherical particles. Magnetic domains of the magnetic powder are randomly oriented, and since the magnetic powder is composed of spherical particles, it does not have shape magnetic anisotropy. Hence, in a case where it is confirmed that the magnetic powder is composed of spherical particles when a cross section of the first functional portion 41A is observed with an electron microscope, and it is confirmed that the magnetic domains are randomly oriented when the cross section is observed with a magnetic force microscope or the like, it can be said that the first functional portion 41A does not have magnetic anisotropy. That is, in the material of the first functional portion 41A, a distinction between easy and hard axes of magnetization is not clear. The relative permeability of the first functional portion 41A is 5 or more.

The second functional portion 41B is located on the second negative direction Y2 side with respect to the first functional portion 41A. When viewed in the direction along the first axis X in a see-through manner, the second functional portion 41B has a rectangular shape elongated in a direction along the second axis Y. That is, the second functional portion 41B has a rectangular shape having two sides parallel to the second axis Y and two sides parallel to the third axis Z. The material of the second functional portion 41B is the same as the material of the first functional portion 41A. That is, the relative permeability of the second functional portion 41B is 5 or more.

As illustrated in FIG. 1, each first via 51 extends in a direction intersecting the first main surface 11A. In the present embodiment, each first via 51 extends through the second layer L2 in the direction orthogonal to the first main surface 11A. The material of the first vias 51 is the same as the material of the first wiring layer 21. Each first via 51 has a substantially frustoconical shape. The diameter of each first via 51 decreases toward the first negative direction X2 side. An end of each first via 51 on the first negative direction X2 side is coupled to the first wiring layer 21. An end of each first via 51 on the first positive direction X1 side is exposed at a surface of the second layer L2. That is, the end of each first via 51 on the first positive direction X1 side is exposed at the first main surface 11A. In FIG. 1, only some of the first vias 51 are denoted by reference signs.

The first interlayer insulating layer 32 is located in the portion of the second layer L2 other than the first functional layer 41 and the first vias 51. That is, the first interlayer insulating layer 32 is located at a position different from the position of the first wiring layer 21 in the direction orthogonal to the first main surface 11A. The first interlayer insulating layer 32 covers the entirety of the first functional layer 41. That is, the first functional layer 41 is located inside the first interlayer insulating layer 32. The first interlayer insulating layer 32 covers the entire peripheral surface of each first via 51. That is, each first via 51 extends through the first interlayer insulating layer 32. The material of the first interlayer insulating layer 32 is the same as the material of the first insulating layer 31. The relative permeability of the first interlayer insulating layer 32 is half or less of the relative permeability of the first functional layer 41. In other words, the relative permeability of the first functional layer 41 is at least twice the relative permeability of the first interlayer insulating layer 32.

The second layer L2 does not include a portion having conductivity higher than that of the first functional layer 41 except for the first vias 51. Accordingly, when viewed in the direction along the first axis X in a see-through manner, the first functional layer 41 overlaps the first wiring layer 21 of the first layer L1 without another wiring part interposed therebetween. The term “another wiring part” in this context refers to any portion having conductivity higher than that of the first functional layer 41, including not only portions extending linearly but also portions functioning as terminals or pads.

The third layer L3 is laminated on a surface of the first layer L1 on the first negative direction X2 side. The third layer L3 includes a second functional layer 42, a second interlayer insulating layer 33, and a plurality of second vias 52.

The second functional layer 42 extends parallel to the first main surface 11A. The second functional layer 42 includes flat-plate-shaped portions. The maximum dimension of the second functional layer 42 in the direction along the first axis X is smaller than the maximum dimension of the third layer L3 in the direction along the first axis X. The second functional layer 42 is not in contact with the first layer L1. The first functional layer 41 is also not in contact with the fourth layer L4. In other words, the second functional layer 42 is embedded in the third layer L3. In the present embodiment, the second functional layer 42 includes a third functional portion 42A and a fourth functional portion 42B that are not coupled to each other within the third layer L3 in which the second functional layer 42 is located.

As illustrated in FIG. 2, when viewed in the direction along the first axis X in a see-through manner, the third functional portion 42A has a rectangular shape elongated in the direction along the third axis Z. That is, the third functional portion 42A has a rectangular shape having two sides parallel to the second axis Y and two sides parallel to the third axis Z. When viewed in the direction along the first axis X in a see-through manner, the dimension of the third functional portion 42A in the direction along the second axis Y is larger than the dimension of the first functional portion 41A in the direction along the second axis Y. When viewed in the direction along the first axis X in a see-through manner, the dimension of the third functional portion 42A in the direction along the third axis Z is slightly larger than the dimension of the first functional portion 41A in the direction along the third axis Z. When viewed in the direction along the first axis X in a see-through manner, the third functional portion 42A overlaps the entirety of the first functional portion 41A. The material of the third functional portion 42A is the same as the material of the first functional portion 41A. That is, the relative permeability of the third functional portion 42A is 5 or more.

The fourth functional portion 42B is located on the second negative direction Y2 side with respect to the third functional portion 42A. When viewed in the direction along the first axis X in a see-through manner, the fourth functional portion 42B has a rectangular shape elongated in the direction along the second axis Y. That is, the fourth functional portion 42B has a rectangular shape having two sides parallel to the second axis Y and two sides parallel to the third axis Z. The outer shape of the fourth functional portion 42B coincides with the outer shape of the second functional portion 41B. When viewed in the direction along the first axis X in a see-through manner, the second functional portion 41B and the fourth functional portion 42B overlap almost completely. The material of the fourth functional portion 42B is the same as the material of the first functional portion 41A. That is, the relative permeability of the fourth functional portion 42B is 5 or more.

In the present embodiment, the sum of the volume of the second functional layer 42 and the volume of the first functional layer 41 is 0.5 times or less the volume of the substrate 11. That is, the volume of the first functional layer 41 is 0.5 times or less the volume of the substrate 11. The volume of the second functional layer 42 is also 0.5 times or less the volume of the substrate 11.

The volumes of the first functional layer 41 and the second functional layer 42 are measured, for example, by the following method. First, the substrate 11 is ground along a plane parallel to the first axis X. A ground cross section of the substrate 11 is imaged, and in the cross section, the maximum dimension of the first functional layer 41 in the direction along the first axis X is measured. In this manner, the maximum dimension of the first functional layer 41 is measured in a cross section at three positions in the substrate 11, and the average value of the maximum dimensions at the three positions is regarded as the thickness of the first functional layer 41. In addition, the substrate 11 is ground in a plane parallel to the first main surface 11A, that is, in a plane parallel to the second axis Y and the third axis Z, such that the first functional layer 41 is exposed. A ground cross section of the substrate 11 is imaged, and the total area of the first functional layer 41 is measured in the cross section. The volume of the first functional layer 41 is calculated by multiplying the total area by the calculated thickness. The volume of the second functional layer 42 is measured by the same or similar procedures.

In the present embodiment, the maximum dimension of the second functional layer 42 in the direction orthogonal to the first main surface 11A is the same as the maximum dimension of the first functional layer 41 in the direction orthogonal to the first main surface 11A. The “maximum dimension” in this context corresponds to the “thickness” mentioned above. The expression “the maximum dimensions are the same” allows manufacturing tolerances. Accordingly, when the difference between the maximum dimensions of the two functional layers is within ±10%, “the maximum dimensions are the same” is deemed satisfied.

As illustrated in FIG. 1, each second via 52 extends in a direction intersecting the first main surface 11A. In the present embodiment, each second via 52 extends through the third layer L3 in the direction orthogonal to the first main surface 11A. The material of the second vias 52 is the same as the material of the first vias 51. Each second via 52 has a substantially frustoconical shape. The diameter of each second via 52 decreases toward the first negative direction X2 side. An end of each second via 52 on the first positive direction X1 side is coupled to the first wiring layer 21. An end of each second via 52 on the first negative direction X2 side is exposed at a surface of the third layer L3. In FIG. 1, only some of the second vias 52 are denoted by reference signs.

The second interlayer insulating layer 33 is located in the portion of the third layer L3 other than the second functional layer 42 and the second vias 52. The second interlayer insulating layer 33 covers the entirety of the second functional layer 42. That is, the second functional layer 42 is located inside the second interlayer insulating layer 33. The second interlayer insulating layer 33 covers the entire peripheral surface of each second via 52. That is, each second via 52 extends through the second interlayer insulating layer 33. The material of the second interlayer insulating layer 33 is the same as the material of the first insulating layer 31. The relative permeability of the second interlayer insulating layer 33 is half or less of the relative permeability of the second functional layer 42. In other words, the relative permeability of the second functional layer 42 is at least twice the relative permeability of the second interlayer insulating layer 33.

The third layer L3 does not include a portion having conductivity higher than that of the second functional layer 42 except for the second vias 52. Accordingly, when viewed in the direction along the first axis X in a see-through manner, the second functional layer 42 overlaps the first wiring layer 21 of the first layer L1 without another wiring part interposed therebetween.

The fourth layer L4 is laminated on a surface of the third layer L3 on the first negative direction X2 side. The fourth layer L4 includes a second wiring layer 22 and a second insulating layer 34.

The material of the second wiring layer 22 is the same as the material of the first wiring layer 21. The second wiring layer 22 extends parallel to the first main surface 11A. In the present embodiment, the second wiring layer 22 extends in a specified wiring pattern in the fourth layer L4. The second wiring layer 22 is coupled to ends of the second vias 52 on the first negative direction X2 side. In FIG. 1, only some portions of the second wiring layer 22 are denoted by reference signs. The second insulating layer 34 is located in the portion of the fourth layer L4 other than the second wiring layer 22. The material of the second insulating layer 34 is the same as the material of the first insulating layer 31.

The fifth layer L5 is laminated on a surface of the fourth layer L4 on the first negative direction X2 side. The fifth layer L5 includes a plurality of third vias 53 and a third insulating layer 35.

Each third via 53 extends in a direction intersecting the first main surface 11A. In the present embodiment, each third via 53 extends through the fifth layer L5 in the direction orthogonal to the first main surface 11A. The material of the third vias 53 is the same as the material of the first vias 51. Each third via 53 has a substantially frustoconical shape. The diameter of each third via 53 decreases toward the first negative direction X2 side. An end of each third via 53 on the first positive direction X1 side is coupled to the second wiring layer 22. An end of each third via 53 on the first negative direction X2 side is exposed at a surface of the fifth layer L5. In FIG. 1, only some of the third vias 53 are denoted by reference signs.

The third insulating layer 35 is located in the portion of the fifth layer L5 other than the third vias 53. The third insulating layer 35 covers the entire peripheral surface of each third via 53. That is, each third via 53 extends through the third insulating layer 35. The material of the third insulating layer 35 is the same as the material of the first insulating layer 31.

The sixth layer L6 is laminated on a surface of the fifth layer L5 on the first negative direction X2 side. That is, the sixth layer L6 is the outermost layer on the first negative direction X2 side in the substrate 11. A surface of the sixth layer L6 on the first negative direction X2 side is the second main surface 11B. The sixth layer L6 includes a plurality of embedded electrodes 61 and a fourth insulating layer 36.

Each embedded electrode 61 extends in a direction parallel to the first main surface 11A. Each embedded electrode 61 has a rectangular shape when viewed in the direction along the first axis X. Although not illustrated, each embedded electrode 61 has a two-layer structure including, in order from the first positive direction X1 side, a layer mainly containing Ni and a layer mainly containing Au. Each embedded electrode 61 is coupled to an end of a corresponding third via 53 on the first negative direction X2 side.

The fourth insulating layer 36 is located in the portion of the sixth layer L6 other than the embedded electrodes 61. The fourth insulating layer 36 covers the peripheral surface of each embedded electrode 61. Accordingly, a portion of each embedded electrode 61 on the first negative direction X2 side is exposed at the second main surface 11B. The material of the fourth insulating layer 36 is the same as the material of the first insulating layer 31. In FIG. 1, boundaries between the layers are illustrated by imaginary dashed dotted lines. However, a clear boundary need not be present between adjacent insulating layers.

As described above, the substrate 11 includes the first wiring layer 21, the first interlayer insulating layer 32, the first functional layer 41, the second wiring layer 22, the second interlayer insulating layer 33, the second functional layer 42, the first vias 51, the second vias 52, and the third vias 53.

The substrate 11 further includes a plurality of outer electrodes 63. The outer electrodes 63 are located on the first main surface 11A. Each outer electrode 63 extends in a direction parallel to the first main surface 11A. Each outer electrode 63 has a rectangular shape when viewed in the direction along the first axis X. Although not illustrated, each outer electrode 63 has a two-layer structure including, in order from the first negative direction X2 side, a layer mainly containing Cu and a layer mainly containing an alloy containing Sn and Ag. Each outer electrode 63 is coupled to a portion of a corresponding first via 51 exposed at the first main surface 11A. In FIG. 1, only some of the outer electrodes 63 are denoted by reference signs.

The semiconductor package 10 includes a plurality of coupling portions 62 and a plurality of semiconductor devices 100.

Each coupling portion 62 is composed of a conductive material such as solder. The number of the coupling portions 62 corresponds to the number of the outer electrodes 63. The coupling portions 62 are applied to the respective outer electrodes 63. The coupling portions 62 cover surfaces of the respective outer electrodes 63 on the first positive direction X1 side. In FIG. 1, only some of the coupling portions 62 are denoted by reference signs.

The semiconductor devices 100 are coupled to the coupling portions 62. That is, the semiconductor devices 100 are mounted on the first main surface 11A with the coupling portions 62 and the outer electrodes 63 interposed therebetween. In the present embodiment, two or more semiconductor devices 100 are mounted on the first main surface 11A. One semiconductor device 100 is coupled to a plurality of outer electrodes 63 with respective coupling portions 62 interposed therebetween. One example of the semiconductor devices 100 is a semiconductor integrated device (CPU) including a plurality of load circuits. Another example of the semiconductor devices 100 is a semiconductor switch such as a power management IC (PMIC). The maximum dimension of each semiconductor device 100 in the direction orthogonal to the first main surface 11A is smaller than the maximum dimension of the substrate 11 in the direction orthogonal to the first main surface 11A.

### First Inductor Wiring Lines and Second Inductor Wiring Lines

As illustrated in FIG. 2, it is assumed that an inductor portion P surrounded by dashed lines in FIG. 1 is viewed in the direction along the first axis X in a see-through manner. In FIG. 2, only the first functional layer 41, the second functional layer 42, the first inductor wiring lines 21A, the second inductor wiring lines 21B, and some of the first vias 51 are illustrated.

As illustrated in FIG. 2, the first wiring layer 21 includes four first inductor wiring lines 21A. The four first inductor wiring lines 21A are arranged side by side in the direction along the third axis Z. Each first inductor wiring line 21A extends linearly parallel to the second axis Y. That is, the number of turns of each first inductor wiring line 21A is 0. In other words, the number of turns of each first inductor wiring line 21A is less than 0.5.

A first line end of each first inductor wiring line 21A on the second positive direction Y1 side is coupled to a first via 51. A second line end of each first inductor wiring line 21A on the second negative direction Y2 side is coupled to another first via 51 different from the first via 51 to which the first line end is coupled. When viewed in the direction along the first axis X in a see-through manner, the entirety of each first inductor wiring line 21A overlaps the third functional portion 42A of the second functional layer 42. When viewed in the direction along the first axis X in a see-through manner, the portion of each first inductor wiring line 21A other than both end portions thereof overlaps the first functional portion 41A of the first functional layer 41. Accordingly, most of each first inductor wiring line 21A is located between the first functional portion 41A and the third functional portion 42A.

The first wiring layer 21 includes four second inductor wiring lines 21B. The second inductor wiring lines 21B are arranged side by side in the direction along the second axis Y. Each second inductor wiring line 21B extends generally in the direction along the third axis Z. A first line end of each second inductor wiring line 21B on the third positive direction Z1 side is coupled to a first via 51. A second line end of each second inductor wiring line 21B on the third negative direction Z2 side is coupled to another first via 51 different from the first via 51 to which the first line end is coupled. When viewed in the direction along the first axis X in a see-through manner, the portion of each second inductor wiring line 21B other than the first line end portion and the second line end portion overlaps the second functional portion 41B of the first functional layer 41 and the fourth functional portion 42B of the second functional layer 42.

In the following description, the four second inductor wiring lines 21B are referred to as, in order from the second positive direction Y1 side, a first line 21B1, a second line 21B2, a third line 21B3, and a fourth line 21B4.

It is assumed that the first line 21B1 is traced from the first line end, which is the end on the third positive direction Z1 side, to the second line end, which is the end on the opposite side. In this case, the first line 21B1 includes a portion extending parallel to the third axis Z, a portion extending obliquely toward the second negative direction Y2 side and the third negative direction Z2 side, a portion extending parallel to the third axis Z, and a portion extending obliquely toward the second positive direction Y1 side and the third negative direction Z2 side.

The number of turns of each second inductor wiring line 21B is defined with reference to a virtual vector. A starting point of the virtual vector is positioned on the center line of the second inductor wiring line 21B. When viewed in the direction along the first axis X, and when the starting point of the virtual vector is moved from a first end of the center line to a second end of the center line, if the angle by which the direction of the virtual vector rotates is 360 degrees, the number of turns is defined as 1.0 turn. When the direction of the virtual vector rotates two or more times, if the rotations are continuous in the same direction, the number of turns is regarded as increasing.

It is assumed that the virtual vector is moved along the first line 21B1. In this case, the virtual vector makes a turn of less than 90 degrees from a state of pointing in the third negative direction Z2 toward the second negative direction Y2 side, then makes a turn of less than 90 degrees toward the second positive direction Y1 side, and further makes a turn of less than 90 degrees toward the second positive direction Y1 side. That is, the virtual vector turns toward the second positive direction Y1 side or the second negative direction Y2 side within a range from several degrees to less than 90 degrees. That is, the number of turns of the first line 21B1 is 0.5 or less.

The second line 21B2 has a shape obtained by inverting the first line 21B1 with respect to a straight line along the third axis Z. The third line 21B3 has the same shape as the first line 21B1. The fourth line 21B4 has the same shape as the second line 21B2. That is, the number of turns of each second inductor wiring line 21B is less than 0.5.

For each first inductor wiring line 21A, it is assumed that a straight line passing through a first line end and a second line end of the first inductor wiring line 21A is defined as a first imaginary straight line V1. Each first imaginary straight line V1 extends parallel to the second axis Y. For each second inductor wiring line 21B, it is assumed that a straight line passing through a first line end and a second line end of the second inductor wiring line 21B is defined as a second imaginary straight line V2. The second imaginary straight line V2 extends generally in the direction along the third axis Z. That is, the first imaginary straight lines V1 and the second imaginary straight lines V2 intersect each other. The first imaginary straight lines V1 and the second imaginary straight lines V2 may be orthogonal to each other.

### Method of Manufacturing Semiconductor Package

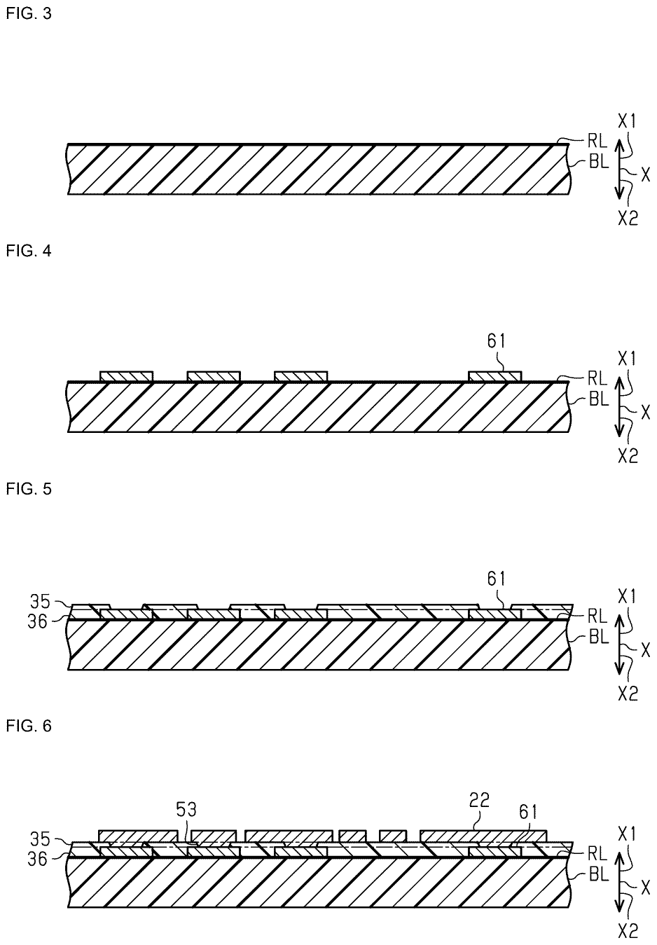

As illustrated in FIG. 3, a plate-shaped base substrate BL is prepared. The material of the base substrate BL is silicon. In the following description, it is assumed that a main surface of the base substrate BL is orthogonal to the first axis X. When viewed in the first negative direction X2, the base substrate BL has, for example, a rectangular shape. The dimensions of the sides of the base substrate BL are sufficient to hold a plurality of substrates 11. Next, a release layer RL is applied to the entire surface on the first positive direction X1 side, that is, the entire upper surface, of the base substrate BL. The release layer RL is, for example, a sheet-shaped member having an adhesive function, such as a tape made of an infrared-curable resin, an acrylic resin-based adhesive, or a polyimide-based adhesive. In FIG. 3, the release layer RL is illustrated with a thick line.

In the next step, as illustrated in FIG. 4, the embedded electrodes 61 are formed on the release layer RL. Specifically, two layers, that is, a layer mainly containing Au and a layer mainly containing Ni positioned in this order from the first negative direction X2 side, are formed by a method such as electroless plating or electrolytic plating. Thus, the embedded electrodes 61 are formed.

In the next step, as illustrated in FIG. 5, the fourth insulating layer 36 and the third insulating layer 35 are formed. Specifically, an insulator is laminated from the first positive direction X1 side of the embedded electrodes 61 and the release layer RL. The material of the insulator is an epoxy resin containing a silica filler. Next, the insulator is irradiated with a laser beam from the first positive direction X1 side. Specifically, portions of the insulator on the first positive direction X1 side of the embedded electrodes 61, where the third vias 53 are to be formed, are irradiated with a laser beam. Thus, the insulator is processed, so that the fourth insulating layer 36 and the third insulating layer 35 are formed.

In the next step, as illustrated in FIG. 6, the third vias 53 and the second wiring layer 22 are formed. The third vias 53 and the second wiring layer 22 are formed by a known technique such as a semi-additive method. After the third vias 53 and the second wiring layer 22 are formed, an insulator is laminated on the first positive direction X1 side of the second wiring layer 22 and the third insulating layer 35. Thus, the second insulating layer 34 and part of the second interlayer insulating layer 33 are formed.

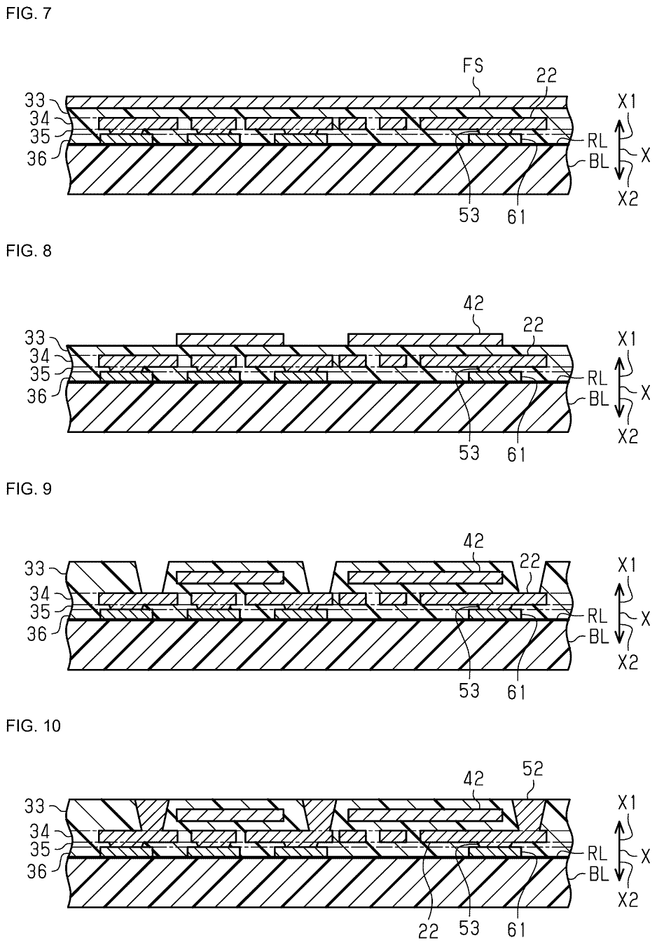

In the next step, as illustrated in FIG. 7, a functional sheet FS is formed. First, the functional sheet FS is laminated on the first positive direction X1 side of the formed part of the second interlayer insulating layer 33. Then, the functional sheet FS is cured. The material of the functional sheet FS is an organic resin containing magnetic powder. In this embodiment, the functional sheet FS has a magnetic powder content of 60 vol % or more.

In the next step, as illustrated in FIG. 8, the second functional layer 42 is formed. That is, the second functional layer 42 is formed by processing the functional sheet FS into desired shapes. For example, the second functional layer 42 is formed by removing portions of the functional sheet FS by a known technique such as dry etching or wet etching.

In the next step, as illustrated in FIG. 9, a remaining part of the second interlayer insulating layer 33 is formed. Specifically, an insulator the same as or similar to that described above is laminated from the first positive direction X1 side of the second functional layer 42 and the formed part of the second interlayer insulating layer 33. Then, the insulator and part of the formed first interlayer insulating layer 32 are irradiated with a laser beam from the first positive direction X1 side. Specifically, portions of the insulator and the second interlayer insulating layer 33 where the second vias 52 are to be formed are irradiated with a laser beam. Thus, the entire part of the second interlayer insulating layer 33 is formed.

In the next step, as illustrated in FIG. 10, the second vias 52 are formed. Specifically, the second vias 52 are formed by copper electrolytic plating.

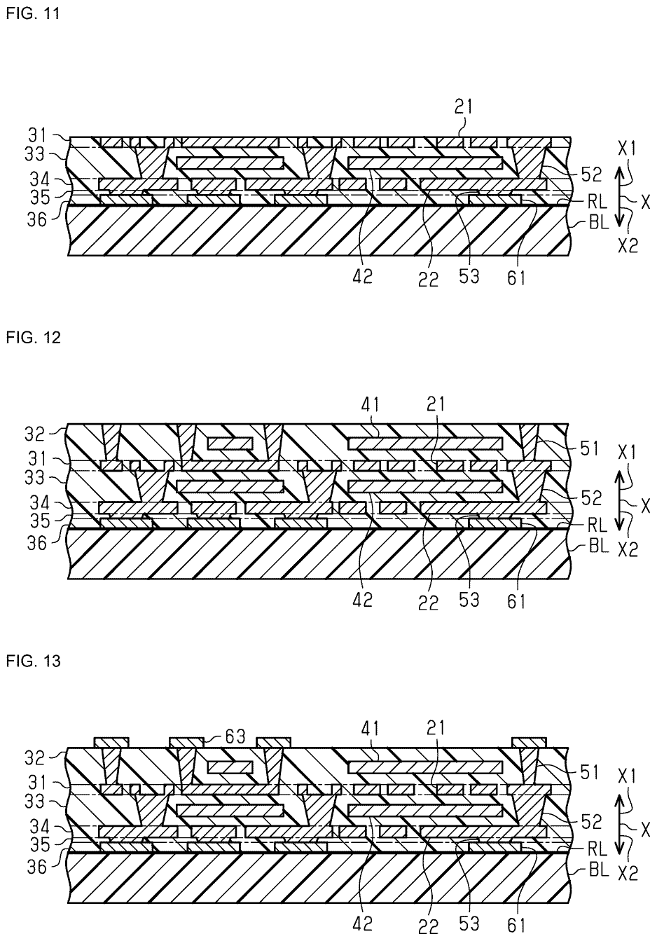

In the next step, as illustrated in FIG. 11, the first insulating layer 31, part of the first interlayer insulating layer 32, and the first wiring layer 21 are formed. The first insulating layer 31 and part of the first interlayer insulating layer 32 are formed, as described above, by laminating an insulator and irradiating the insulator with a laser beam. The first wiring layer 21 is formed by a known technique such as a semi-additive method.

In the next step, as illustrated in FIG. 12, a remaining part of the first interlayer insulating layer 32, the first functional layer 41, and the first vias 51 are formed. The first interlayer insulating layer 32, the first functional layer 41, and the first vias 51 are formed in the same or a similar manner as described with reference to FIGS. 7 to 10.

In the next step, as illustrated in FIG. 13, the outer electrodes 63 are formed. Specifically, the outer electrodes 63 are formed by a known technique such as a semi-additive method or a subtractive method. The present embodiment employs a semi-additive method to form two layers composed of a layer mainly containing Cu and a layer mainly containing an alloy containing Sn and Ag positioned in this order from the first negative direction X2 side. Thus, the outer electrodes 63 are formed.

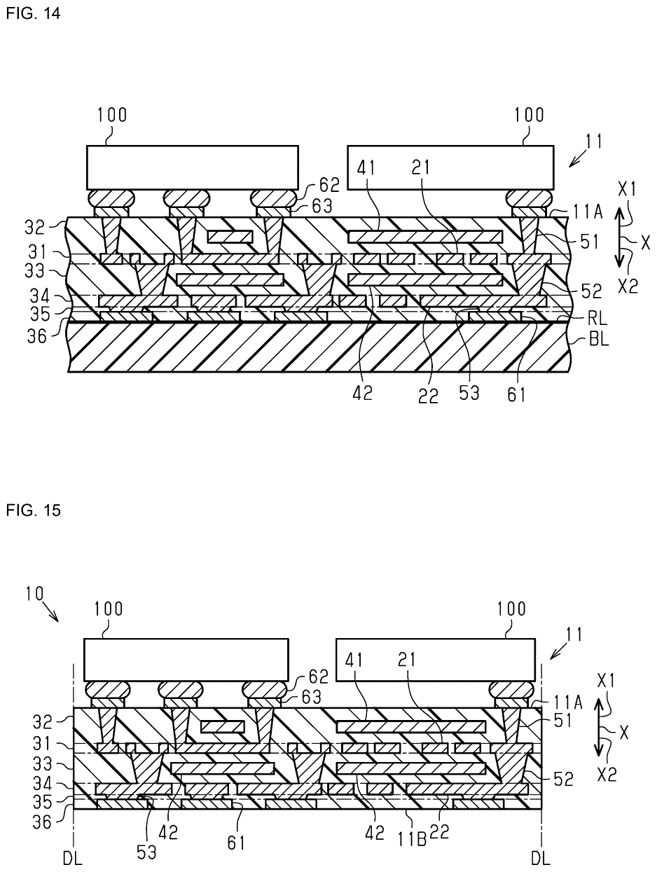

In the next step, as illustrated in FIG. 14, the semiconductor devices 100 are mounted. Specifically, terminals of the semiconductor devices 100 are first coupled with solder onto the outer electrodes 63. The solder after coupling serves as the coupling portions 62.

In the next step, as illustrated in FIG. 15, the base substrate BL and the release layer RL are removed, and a singulation process is performed to obtain substrates 11. Specifically, the base substrate BL and the release layer RL are first removed by cutting. Thus, a structure including a plurality of substrates 11 is formed. The structure is cut along dashed lines DL with a dicing machine so as to be singulated into the substrates 11 with a desired size. Thus, the semiconductor packages 10 are formed. In FIGS. 3 to 15, only some of members may be denoted by reference signs.

### Advantageous Effects of First Embodiment

(1-1) In the first embodiment, the relative permeability of the first functional layer 41 is at least twice the relative permeability of the first interlayer insulating layer 32. In this configuration, since the relative permeability of the first functional layer 41 is relatively high, the first functional layer 41 functions as cores of inductors. Then, since the first functional layer 41 includes flat-plate-shaped portions extending inside the first interlayer insulating layer 32, it is not necessary to increase the dimension of the first functional layer 41 greatly in the direction orthogonal to the first main surface 11A in order to assign enough volume to the first functional layer 41. This configuration achieves a thin design while enabling part of the substrate 11 to function as inductors having desired characteristics.

(1-2) In the first embodiment, the number of turns of each first inductor wiring line 21A is 0.5 or less. The relative permeability of the first functional layer 41 is 5 or more. In this configuration, since the relative permeability of the first functional layer 41 is high, a desired inductance can be obtained without increasing the number of turns of each first inductor wiring line 21A. In addition, since the number of turns of each first inductor wiring line 21A is 0.5 or less as mentioned above, the area to be assigned to the first inductor wiring lines 21A can be small. Accordingly, an increase in dimensions of the substrate 11 in the directions parallel to the first main surface 11A can be suppressed. In this regard, the same applies to the second inductor wiring lines 21B.

(1-3) If the first functional layer 41 and the second functional layer 42 have magnetic anisotropy, it is preferable to arrange the inductor wiring lines along easy axes of magnetization. That is, when the first functional layer 41 has magnetic anisotropy, the shapes and arrangement of the inductor wiring lines may be restricted. In the first embodiment, the first functional layer 41 and the second functional layer 42 do not have magnetic anisotropy. In a configuration in which the first functional layer 41 and the second functional layer 42 do not have magnetic anisotropy, even if the first imaginary straight lines V1 of the first inductor wiring lines 21A and the second imaginary straight lines V2 of the second inductor wiring lines 21B intersect each other, deterioration of characteristics as inductors in relation to the magnetic anisotropy of the first functional layer 41 and the second functional layer 42 can be suppressed. That is, with this configuration, the degree of freedom in designing the first inductor wiring lines 21A and the second inductor wiring lines 21B increases.

(1-4) In the first embodiment, the substrate 11 further includes the second functional layer 42. The material of the second functional layer 42 is the same as the material of the first functional layer 41. When the first functional layer 41 and the second functional layer 42 have the same material as mentioned above, the first functional layer 41 and the second functional layer 42 can be formed by the same or similar steps when manufacturing the semiconductor package 10. Accordingly, an increase in complexity of manufacturing steps can be suppressed.

(1-5) In the first embodiment, the maximum dimension of the second functional layer 42 in the direction orthogonal to the first main surface 11A is the same as the maximum dimension of the first functional layer 41 in the direction orthogonal to the first main surface 11A. In this configuration, it is not necessary to individually control the thicknesses of the insulating layers located in the same layer as each functional layer in a manufacturing process of the semiconductor package 10. That is, the second interlayer insulating layer 33 and the first interlayer insulating layer 32 described with reference to FIG. 12 can be formed to have the same thickness dimension.

(1-6) In the first embodiment, the sum of the volume of the second functional layer 42 and the volume of the first functional layer 41 is 0.5 times or less the volume of the substrate 11. When the volume of each functional layer is smaller than the volume of the substrate 11 as in this configuration, a special process is not required when forming each functional layer in the substrate 11. That is, since the semiconductor package 10 including the first functional layer 41 and the second functional layer 42 can be manufactured by conventional substrate processes, the semiconductor package 10 can be formed at low cost. Since the volume of portions other than the functional layers, in particular, the volume of insulating layers, is large in the entire substrate 11, this configuration enables the coefficient of thermal expansion to be uniform in the entire semiconductor package 10. Accordingly, occurrence of local thermal deformation in the semiconductor package 10 can be suppressed.

### Second Embodiment

Hereinafter, a second embodiment of the semiconductor package will be described.

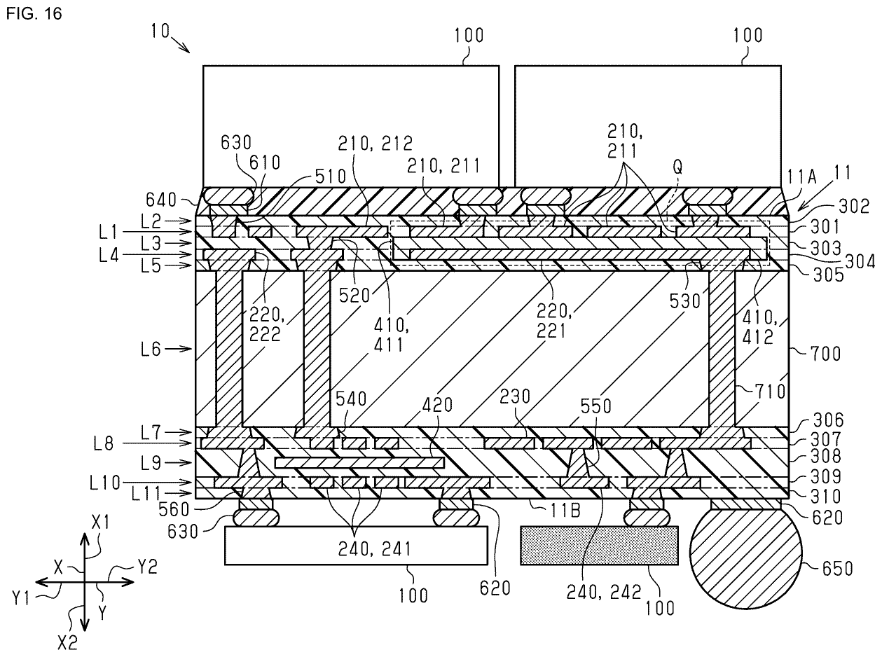

As illustrated in FIG. 16, a semiconductor package 10 of the second embodiment includes a first main surface 11A and a second main surface 11B. The first main surface 11A and the second main surface 11B are the same as those in the first embodiment. A first axis X, a second axis Y, and a third axis Z are defined in the same manner as those in the first embodiment.

The substrate 11 includes a first layer L1 to an eleventh layer L11. When viewed in the direction along the first axis X in a see-through manner, outer shapes of the first layer L1 to the eleventh layer L11 are each rectangular. The layers of the substrate 11 are arranged from the first positive direction X1 side toward the first negative direction X2 side in the order of the second layer L2, the first layer L1, the third layer L3, the fourth layer L4, the fifth layer L5, the sixth layer L6, the seventh layer L7, the eighth layer L8, the ninth layer L9, the tenth layer L10, and the eleventh layer L11.

The first layer L1 is a layer at the second position from the first positive direction X1 side among the layers of the substrate 11. The first layer L1 includes a first wiring layer 210 and a first insulating layer 301.

The material of the first wiring layer 210 is the same as the material of the first wiring layer 21 in the first embodiment. The first wiring layer 210 extends parallel to the first main surface 11A. In the present embodiment, the first wiring layer 210 includes a plurality of first electrodes 211 and other wiring lines 212. The first electrodes 211 will be described later.

The other wiring lines 212 extend in specified wiring patterns in the second layer L2. The other wiring lines 212 may be coupled to some of the first electrodes 211, but need not be coupled thereto. In FIG. 16, only some of the other wiring lines 212 are denoted by reference signs.

The first insulating layer 301 is located in the portion of the first layer L1 other than the first wiring layer 210. The material of the first insulating layer 301 is the same as the material of the first insulating layer 31 in the first embodiment.

The second layer L2 is laminated on a surface of the first layer L1 on the first positive direction X1 side. That is, the second layer L2 is the outermost layer on the first positive direction X1 side in the substrate 11. A surface of the second layer L2 on the first positive direction X1 side is the first main surface 11A. The second layer L2 includes a plurality of first vias 510 and a second insulating layer 302.

Each first via 510 extends in a direction intersecting the first main surface 11A. In the present embodiment, each first via 510 extends through the second layer L2 in the direction orthogonal to the first main surface 11A. The material of the first vias 510 is the same as the material of the first wiring layer 210. Each first via 510 has a substantially frustoconical shape. The diameter of each first via 510 decreases toward the first negative direction X2 side. An end of each first via 510 on the first negative direction X2 side is coupled to the first wiring layer 210. An end of each first via 510 on the first positive direction X1 side is exposed at a surface of the second layer L2. That is, the end of each first via 510 on the first positive direction X1 side is exposed at the first main surface 11A. In FIG. 16, only some of the first vias 510 are denoted by reference signs.

The second insulating layer 302 is located in the portion of the second layer L2 other than the first vias 510. The material of the second insulating layer 302 is the same as the material of the first insulating layer 301.

The third layer L3 is laminated on a surface of the first layer L1 on the first negative direction X2 side. The third layer L3 includes a first functional portion 411 that is part of a first functional layer 410, a first interlayer insulating layer 303, and a plurality of second vias 520.

In the present embodiment, the first functional layer 410 is generally in a flat plate shape. The first functional layer 410 spans the third layer L3 and the fourth layer L4. A portion of the first functional layer 410 located in the third layer L3 is referred to as the first functional portion 411, and a portion located in the fourth layer L4 is referred to as a second functional portion 412.

The first functional portion 411 extends parallel to the first main surface 11A. The first functional portion 411 has a flat plate shape. The maximum dimension of the first functional portion 411 in the direction along the first axis X is the same as the maximum dimension of the third layer L3 in the direction along the first axis X.

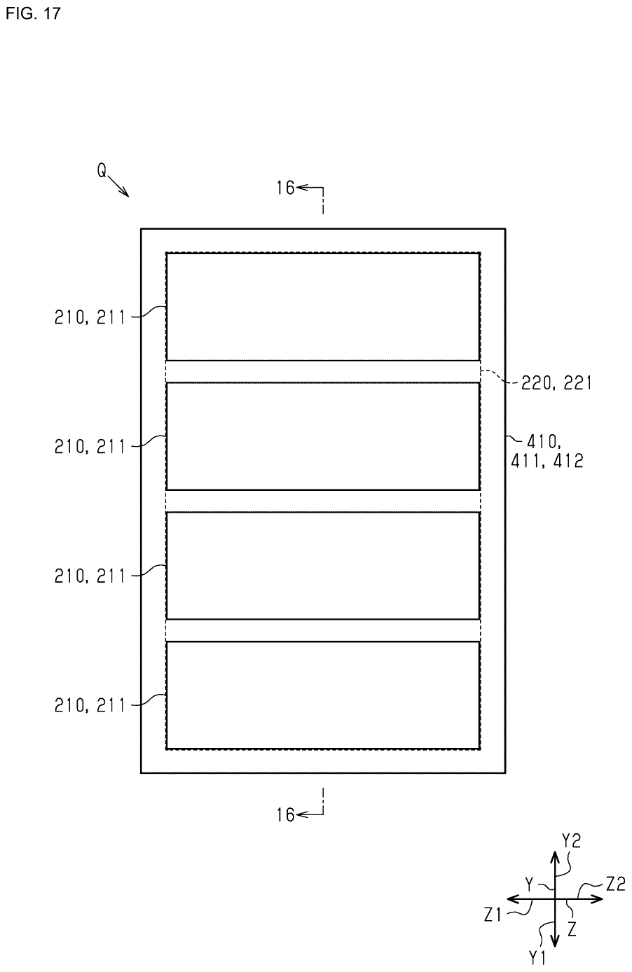

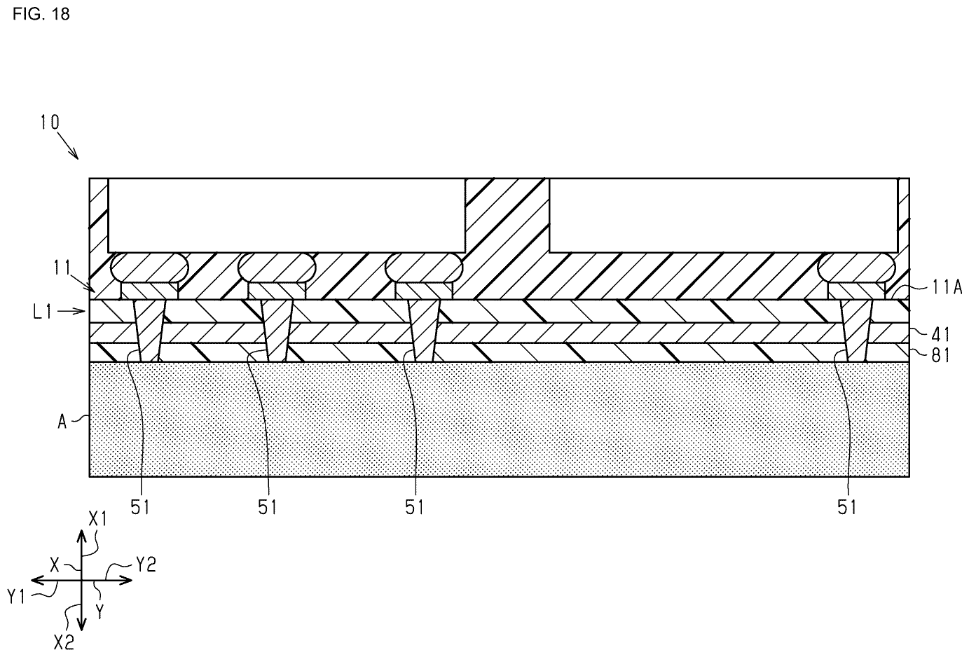

As illustrated in FIG. 17, when viewed in the direction along the first axis X in a see-through manner, the first functional portion 411 has a rectangular shape elongated in the direction along the second axis Y. That is, the first functional portion 411 has a rectangular shape having two sides parallel to the second axis Y and two sides parallel to the third axis Z. The first functional portion 411 is in contact with a surface of the first wiring layer 210 facing the first negative direction X2. In other words, the first functional layer 410 is in contact with a surface of the first wiring layer 210 facing a direction orthogonal to the first main surface 11A. That is, the first functional portion 411 is in contact with a surface of the first wiring layer 210 facing a direction orthogonal to the first main surface 11A.

The material of the first functional portion 411 is an organic resin containing an inorganic filler. In this embodiment, the inorganic filler is barium titanate. In this embodiment, the organic resin is an epoxy resin. The organic resin is not limited to an epoxy-based resin and may be a polyimide-based resin, a liquid crystal polymer-based resin, an acrylic-based resin, a phenol-based resin, or a combination of some of these. The first functional portion 411 may be formed by sputtering using SiO₂, SiN, TaO, or an inorganic oxide including a high-κ material. In the present embodiment, the first functional portion 41A has an inorganic filler content of 60 vol % or more.

As illustrated in FIG. 16, each second via 520 extends in a direction intersecting the first main surface 11A. In the present embodiment, each second via 520 extends through the third layer L3 in the direction orthogonal to the first main surface 11A. The material of the second vias 520 is the same as the material of the first vias 510. Each second via 520 has a substantially frustoconical shape. The diameter of each second via 520 decreases toward the first negative direction X2 side. An end of each second via 520 on the first positive direction X1 side is coupled to the first wiring layer 210. An end of each second via 520 on the first negative direction X2 side is exposed at a surface of the third layer L3.

The first interlayer insulating layer 303 is located in the portion of the third layer L3 other than the first functional portion 411 and the second vias 520. The first interlayer insulating layer 303 covers the entire peripheral surface of the first functional portion 411 and the entire peripheral surface of each second via 520. That is, the first functional portion 411 and each second via 520 extend through the first interlayer insulating layer 303. The material of the first interlayer insulating layer 303 is the same as the material of the first insulating layer 301. The relative permittivity of the first interlayer insulating layer 303 is half or less of the relative permittivity of the first functional portion 411. In other words, the relative permittivity of the first functional layer 410 is at least twice the relative permittivity of the first interlayer insulating layer 303.

The fourth layer L4 is laminated on a surface of the third layer L3 on the first negative direction X2 side. The fourth layer L4 includes a second wiring layer 220, a second functional portion 412, and a third insulating layer 304.

The material of the second wiring layer 220 is the same as the material of the first wiring layer 210. The second wiring layer 220 extends parallel to the first main surface 11A. That is, the second wiring layer 220 is located at a position different from the position of the first wiring layer 210 in the direction orthogonal to the first main surface 11A. The second wiring layer 220 is located on the first negative direction X2 side with respect to the first interlayer insulating layer 303. In other words, the first interlayer insulating layer 303 is located between the first wiring layer 210 and the second wiring layer 220.

In the present embodiment, the second wiring layer 220 includes a second electrode 221 and other wiring lines 222. The second electrode 221 will be described later.

The other wiring lines 222 extend in specified wiring patterns in the second layer L2. The other wiring lines 222 may be coupled to the second electrode 221, but need not be coupled thereto. In FIG. 16, only some of the other wiring lines 222 are denoted by reference signs.

The material of the second functional portion 412 is the same as the material of the first functional portion 411. The second functional portion 412 extends parallel to the first main surface 11A. The maximum dimension of the second functional portion 412 in the direction along the first axis X is the same as the maximum dimension of the fourth layer L4 in the direction along the first axis X.

As illustrated in FIG. 17, the second functional portion 412 has a rectangular frame shape extending along an outer shape of the first functional portion 411 when viewed in the direction along the first axis X in a see-through manner. A surface of the second functional portion 412 on the first positive direction X1 side is coupled to the first functional portion 411. As described above, the second functional portion 412 is part of the first functional layer 410. That is, there is no boundary between the second functional portion 412 and the first functional portion 411. When viewed in the direction along the first axis X in a see-through manner, the first functional layer 410 including the second functional portion 412 and the first functional portion 411 overlaps the first wiring layer 210 and the second wiring layer 220 without another wiring part interposed therebetween.

As illustrated in FIG. 16, the second functional portion 412 covers the surfaces of the second electrode 221 facing the directions parallel to the first main surface 11A. The first functional portion 411 covers the surface of the second electrode 221 facing the first positive direction X1. That is, the first functional layer 410 covers the surfaces of the second electrode 221 other than the surface on the first negative direction X2 side. In other words, the first functional layer 410 is in contact with the surfaces of the second wiring layer 220 facing the directions parallel to the first main surface 11A. The first functional layer 410 is also in contact with the surface of the second wiring layer 220 facing a direction orthogonal to the first main surface 11A.

The third insulating layer 304 is located in the portion of the fourth layer L4 other than the second wiring layer 220 and the second functional portion 412. The material of the third insulating layer 304 is the same as the material of the first insulating layer 301.

The fifth layer L5 is laminated on a surface of the fourth layer L4 on the first negative direction X2 side. The fifth layer L5 includes a plurality of third vias 530 and a fourth insulating layer 305.

Each third via 530 extends in a direction intersecting the first main surface 11A. In the present embodiment, each third via 530 extends through the fifth layer L5 in the direction orthogonal to the first main surface 11A. The material of the third vias 530 is the same as the material of the first vias 510. Each third via 530 has a substantially frustoconical shape. The diameter of each third via 530 decreases toward the first negative direction X2 side. An end of each third via 530 on the first positive direction X1 side is coupled to the second wiring layer 220. An end of each third via 530 on the first negative direction X2 side is exposed at a surface of the fifth layer L5. In FIG. 16, only some of the third vias 530 are denoted by reference signs.

The fourth insulating layer 305 is located in the portion of the fifth layer L5 other than the third vias 530. The fourth insulating layer 305 covers the entire peripheral surface of each third via 530. That is, each third via 530 extends through the fourth insulating layer 305. The material of the fourth insulating layer 305 is the same as the material of the first insulating layer 301.

The sixth layer L6 is laminated on a surface of the fifth layer L5 on the first negative direction X2 side. The sixth layer L6 includes a plurality of through wiring lines 710 and a core portion 700.

Each through wiring line 710 extends in a direction intersecting the first main surface 11A. In the present embodiment, each through wiring line 710 extends through the sixth layer L6 in the direction orthogonal to the first main surface 11A. The material of the through wiring lines 710 is the same as the material of the first vias 510. Each through wiring line 710 has a substantially cylindrical shape. An end of each through wiring line 710 on the first positive direction X1 side is coupled to a corresponding third via 530. That is, each through wiring line 710 is coupled to the second wiring layer 220 with a corresponding third via 530 interposed therebetween. An end of each through wiring line 710 on the first negative direction X2 side is exposed at a surface of the sixth layer L6. In FIG. 16, only some of the through wiring lines 710 are denoted by reference signs.

The core portion 700 is located in the portion of the sixth layer L6 other than the through wiring lines 710. The core portion 700 covers the entire peripheral surface of each through wiring line 710. That is, each through wiring line 710 extends through the core portion 700 in the direction orthogonal to the first main surface 11A. In the present embodiment, the maximum dimension of the core portion 700 in the direction along the first axis X is larger than the maximum dimension of the first interlayer insulating layer 303 in the direction along the first axis X.

The material of the core portion 700 is, for example, an epoxy resin containing glass cloth, glass filler, and the like; glass; ceramic; or the like. The bending strength of the core portion 700 is greater than the bending strength of the first interlayer insulating layer 303. The bending strength is measured, for example, in accordance with a bending strength test in conformity with JIS K6911, ASTM C1161, ASTM F2180, or the like. In this test, a core portion 700 to be measured is formed such that the sixth layer L6 only includes the core portion 700 without the through wiring lines 710. In this test, a first interlayer insulating layer 303 to be measured is formed such that the third layer L3 only includes the first interlayer insulating layer 303 without the first functional portion 411 and the second vias 520.

The seventh layer L7 is laminated on a surface of the sixth layer L6 on the first negative direction X2 side. The seventh layer L7 includes a plurality of fourth vias 540 and a fifth insulating layer 306.

Each fourth via 540 extends in a direction intersecting the first main surface 11A. In the present embodiment, each fourth via 540 extends through the seventh layer L7 in the direction orthogonal to the first main surface 11A. The material of the fourth vias 540 is the same as the material of the first vias 510. Each fourth via 540 has a substantially frustoconical shape. The diameter of each fourth via 540 decreases toward the first positive direction X1 side. An end of each fourth via 540 on the first positive direction X1 side is coupled to a corresponding through wiring line 710. An end of each fourth via 540 on the first negative direction X2 side is exposed at a surface of the seventh layer L7. In FIG. 16, only some of the fourth vias 540 are denoted by reference signs.

The fifth insulating layer 306 is located in the portion of the seventh layer L7 other than the fourth vias 540. The fifth insulating layer 306 covers the entire peripheral surface of each fourth via 540. That is, each fourth via 540 extends through the fifth insulating layer 306. The material of the fifth insulating layer 306 is the same as the material of the first insulating layer 301.

The eighth layer L8 is laminated on a surface of the seventh layer L7 on the first negative direction X2 side. The eighth layer L8 includes a third wiring layer 230 and a sixth insulating layer 307.

The material of the third wiring layer 230 is the same as the material of the first wiring layer 210. The third wiring layer 230 extends parallel to the first main surface 11A. In the present embodiment, the third wiring layer 230 extends in a specified wiring pattern in the eighth layer L8. In FIG. 16, only some portions of the third wiring layer 230 are denoted by reference signs. The third wiring layer 230 is coupled to ends of the fourth vias 540 on the first negative direction X2 side. That is, each through wiring line 710 is coupled to the third wiring layer 230 with a corresponding fourth via 540 interposed therebetween. In this manner, the through wiring lines 710 extend through the core portion 700 in the direction orthogonal to the first main surface 11A and couple the second wiring layer 220 and the third wiring layer 230.

The sixth insulating layer 307 is located in the portion of the eighth layer L8 other than the third wiring layer 230. The material of the sixth insulating layer 307 is the same as the material of the first insulating layer 301.

The ninth layer L9 is laminated on a surface of the eighth layer L8 on the first negative direction X2 side. The ninth layer L9 includes a second functional layer 420, a second interlayer insulating layer 308, and a plurality of fifth vias 550.

The second functional layer 420 extends parallel to the first main surface 11A. The second functional layer 420 has a flat plate shape. The maximum dimension of the second functional layer 420 in the direction along the first axis X is smaller than the maximum dimension of the ninth layer L9 in the direction along the first axis X. The second functional layer 420 is not in contact with the eighth layer L8. The second functional layer 420 is also not in contact with the tenth layer L10. In other words, the second functional layer 420 is embedded in the ninth layer L9.

In the present embodiment, the sum of the volume of the second functional layer 420 and the volume of the first functional layer 410 is less than 0.5 times the volume of the substrate 11. That is, the volume of the first functional layer 410 is less than 0.5 times the volume of the substrate 11. The volume of the second functional layer 420 is less than 0.5 times the volume of the substrate 11. The volumes of the first functional layer 410 and the second functional layer 420 can be measured in the same or a similar manner as the method described in the first embodiment. In the present embodiment, the maximum dimension of the second functional layer 420 in the direction orthogonal to the first main surface 11A is the same as the maximum dimension of the first functional layer 410 in the direction orthogonal to the first axis X.

Each fifth via 550 extends in a direction intersecting the first main surface 11A. In the present embodiment, each fifth via 550 extends through the ninth layer L9 in the direction orthogonal to the first main surface 11A. The material of the fifth vias 550 is the same as the material of the first vias 510. Each fifth via 550 has a substantially frustoconical shape. The diameter of each fifth via 550 decreases toward the first positive direction X1 side. An end of each fifth via 550 on the first positive direction X1 side is coupled to the third wiring layer 230. An end of each fifth via 550 on the first negative direction X2 side is exposed at a surface of the ninth layer L9. In FIG. 16, only some of the fifth vias 550 are denoted by reference signs.

The second interlayer insulating layer 308 is located in the portion of the ninth layer L9 other than the second functional layer 420 and the fifth vias 550. The second interlayer insulating layer 308 covers the entirety of the second functional layer 420. That is, the second functional layer 420 is located inside the second interlayer insulating layer 308. The second interlayer insulating layer 308 is in direct contact with a surface of the eighth layer L8 on the first negative direction X2 side. That is, the second interlayer insulating layer 308 is adjacent to the third wiring layer 230 in the direction orthogonal to the first main surface 11A without another wiring part interposed therebetween. The second interlayer insulating layer 308 covers the entire peripheral surface of each fifth via 550. That is, each fifth via 550 extends through the second interlayer insulating layer 308. The material of the second interlayer insulating layer 308 is the same as the material of the first insulating layer 301. The relative permeability of the second interlayer insulating layer 308 is half or less of the relative permeability of the second functional layer 420. In other words, the relative permeability of the second functional layer 420 is at least twice the relative permeability of the second interlayer insulating layer 308.

The ninth layer L9 does not include a portion having conductivity higher than that of the second functional layer 420 except for the fifth vias 550. Accordingly, when viewed in the direction along the first axis X in a see-through manner, the second functional layer 420 overlaps the third wiring layer 230 of the eighth layer L8 without another wiring part interposed therebetween.

The tenth layer L10 is laminated on a surface of the ninth layer L9 on the first negative direction X2 side. The tenth layer L10 includes a fourth wiring layer 240 and a seventh insulating layer 309.

The material of the fourth wiring layer 240 is the same as the material of the first wiring layer 210. The fourth wiring layer 240 extends parallel to the first main surface 11A. The fourth wiring layer 240 includes inductor wiring lines 241 and other wiring lines 242 different from the inductor wiring lines 241. When viewed in the direction along the first axis X in a see-through manner, some of the inductor wiring lines 241 overlap the second functional layer 420. The other wiring lines 242 extend in specified wiring patterns in the tenth layer L10. In FIG. 16, only some of the other wiring lines 242 are denoted by reference signs.

The seventh insulating layer 309 is located in the portion of the tenth layer L10 other than the fourth wiring layer 240. The material of the seventh insulating layer 309 is the same as the material of the first insulating layer 301.

The eleventh layer L11 is laminated on a surface of the tenth layer L10 on the first negative direction X2 side. That is, the eleventh layer L11 is the outermost layer on the first negative direction X2 side in the substrate 11. A surface of the eleventh layer L11 on the first negative direction X2 side is the second main surface 11B. The eleventh layer L11 includes a plurality of sixth vias 560 and an eighth insulating layer 310.

Each sixth via 560 extends in a direction intersecting the first main surface 11A. In the present embodiment, each sixth via 560 extends through the eleventh layer L11 in the direction orthogonal to the first main surface 11A. The material of the sixth vias 560 is the same as the material of the first vias 510. Each sixth via 560 has a substantially frustoconical shape. The diameter of each sixth via 560 decreases toward the first positive direction X1 side. An end of each sixth via 560 on the first positive direction X1 side is coupled to the fourth wiring layer 240. An end of each sixth via 560 on the first negative direction X2 side is exposed at a surface of the eleventh layer L11. That is, the end of each sixth via 560 on the first negative direction X2 side is exposed at the second main surface 11B. In FIG. 16, only some of the sixth vias 560 are denoted by reference signs.

The eighth insulating layer 310 is located in the portion of the eleventh layer L11 other than the sixth vias 560. The eighth insulating layer 310 covers the entire peripheral surface of each sixth via 560. That is, each sixth via 560 extends through the eighth insulating layer 310. The material of the eighth insulating layer 310 is the same as the material of the first insulating layer 301.

As described above, the substrate 11 includes the first wiring layer 210, the second wiring layer 220, the third wiring layer 230, and the fourth wiring layer 240. The substrate 11 includes the first interlayer insulating layer 303, the second interlayer insulating layer 308, the first functional layer 410, and the second functional layer 420. The substrate 11 also includes the first vias 510 to the sixth vias 560 and the through wiring lines 710. The substrate 11 also includes the core portion 700 inside the substrate 11.

As described above, the first functional layer 410 and the second functional layer 420 are located on opposite sides of the core portion 700 in the direction orthogonal to the first main surface 11A. The substrate 11 does not include a layer made of the same material as the second functional layer 420 on the side closer to the first main surface 11A than the core portion 700. Similarly, the substrate 11 does not include a layer made of the same material as the first functional layer 410 on the side farther from the first main surface 11A than the core portion 700. In other words, the first functional layer 410 is located on only one of the two sides: the side closer to the first main surface 11A than the core portion 700 and the side farther from the first main surface 11A than the core portion 700. The substrate 11 does not include a layer made of the same material as the first functional layer 410 on the other of the two sides: the side closer to the first main surface 11A than the core portion 700 and the side farther from the first main surface 11A than the core portion 700.

In the present embodiment, the second interlayer insulating layer 308 is located at a position different from the position of the first interlayer insulating layer 303 in the direction orthogonal to the first main surface 11A. The second interlayer insulating layer 308 is located on the side farther from the first main surface 11A than the first interlayer insulating layer 303. The relative permittivity of the first functional layer 410 is at least twice the relative permittivity of the first interlayer insulating layer 303, and the relative permeability of the second functional layer 420 is at least twice the relative permeability of the second interlayer insulating layer 308.

The substrate 11 further includes a plurality of first outer electrodes 610 and a plurality of second outer electrodes 620. The first outer electrodes 610 are located on the first main surface 11A. Each first outer electrode 610 extends in a direction parallel to the first main surface 11A. Each first outer electrode 610 has a rectangular shape when viewed in the direction along the first axis X. Although not illustrated, each first outer electrode 610 has a two-layer structure including, in order from the first negative direction X2 side, a layer mainly containing Cu and a layer mainly containing an alloy containing Sn and Ag. The first outer electrodes 610 are coupled to the respective first vias 510 exposed at the first main surface 11A. In FIG. 16, only some of the first outer electrodes 610 are denoted by reference signs.

The second outer electrodes 620 are located on the second main surface 11B. Each second outer electrode 620 extends in a direction parallel to the second main surface 11B. Each second outer electrode 620 has a rectangular shape when viewed in the direction along the first axis X. Although not illustrated, each second outer electrode 620 has a two-layer structure including, in order from the first positive direction X1 side, a layer mainly containing Cu and a layer mainly containing an alloy containing Sn and Ag. The second outer electrodes 620 are coupled to the respective sixth vias 560 exposed at the second main surface 11B. In FIG. 16, only some of the second outer electrodes 620 are denoted by reference signs.

The semiconductor package 10 includes a plurality of coupling portions 630, a land portion 650, a plurality of semiconductor devices 100, and an underfill 640.

Each coupling portion 630 is composed of a conductive material such as solder. The coupling portions 630 are applied to the corresponding ones of the first and second outer electrodes 610 and 620. In the present embodiment, some of the second outer electrodes 620 are not covered with the coupling portions 630. The coupling portions 630 coupled to first outer electrodes 610 cover the surfaces on the first positive direction X1 side of the first outer electrodes 610. The coupling portions 630 coupled to second outer electrodes 620 cover the surfaces on the first negative direction X2 side of the second outer electrodes 620. In FIG. 16, only some of the coupling portions 630 are denoted by reference signs.

The land portion 650 is composed of a conductive material such as solder. The land portion 650 is applied to the second outer electrodes 620 not covered with the coupling portions 630. The land portion 650 covers surfaces of the second outer electrodes 620 on the first negative direction X2 side. The land portion 650 is a member for coupling a mother board that is mounted on the second main surface 11B. The volume of the land portion 650 is larger than the volume of each coupling portion 630.

The semiconductor devices 100 are coupled to the coupling portions 630. That is, some of the semiconductor devices 100 are mounted on the first main surface 11A with the corresponding coupling portions 630 and the first outer electrodes 610 interposed therebetween. The others of the semiconductor devices 100 are mounted on the second main surface 11B with the corresponding coupling portions 630 and the second outer electrodes 620 interposed therebetween. In the present embodiment, two or more semiconductor devices 100 are mounted on the first main surface 11A. In the present embodiment, two or more semiconductor devices 100 are mounted on the second main surface 11B. At least one selected from the semiconductor devices 100 mounted on the first main surface 11A is a semiconductor integrated circuit including a plurality of load circuits. At least one selected from the semiconductor devices 100 mounted on the first main surface 11A is a PMIC. In addition, at least one selected from the semiconductor devices 100 mounted on the second main surface 11B is a PMIC. The maximum dimension of each semiconductor device 100 in the direction orthogonal to the first main surface 11A is smaller than the maximum dimension of the substrate 11 in the direction orthogonal to the first main surface 11A.

The underfill 640 is located on the first positive direction X1 side with respect to the first main surface 11A and on the first negative direction X2 side with respect to the semiconductor devices 100. That is, the underfill 640, which is between the semiconductor devices 100 and the first main surface 11A, covers the periphery of the first outer electrodes 610 and the coupling portions 630. The material of the underfill 640 is, for example, an epoxy resin. The material of the underfill 640 is not limited to an epoxy resin and may be a polyimide-based resin, a liquid crystal polymer-based resin, an acrylic-based resin, a phenol-based resin, or a combination of some of these. The underfill 640 may contain an inorganic filler such as a silica filler.

### First Electrodes and Second Electrode

As illustrated in FIG. 17, it is assumed that a capacitor portion Q surrounded by dashed lines in FIG. 16 is viewed in the direction along the first axis X in a see-through manner. In FIG. 17, only the first functional layer 410, the first electrodes 211, and the second electrode 221 are illustrated.

As illustrated in FIG. 17, the first wiring layer 210 includes four first electrodes 211. When viewed in the direction along the first axis X in a see-through manner, each first electrode 211 has a rectangular shape elongated in the direction along the third axis Z. That is, each first electrode 211 has a rectangular shape having two sides parallel to the second axis Y and two sides parallel to the third axis Z. Each of the four first electrodes 211 has the same shape. The four first electrodes 211 are arranged at intervals in the direction along the second axis Y.

When viewed in the direction along the first axis X in a see-through manner, the second electrode 221 has a rectangular shape elongated in the direction along the second axis Y. That is, the second electrode 221 has a rectangular shape having two sides parallel to the second axis Y and two sides parallel to the third axis Z. When viewed in the direction along the first axis X in a see-through manner, the second electrode 221 overlaps the entire region of the four first electrodes 211 substantially completely.

The first functional layer 410 overlaps the first electrodes 211 and the second electrode 221 in the direction along the first axis X without another wiring part interposed therebetween. When viewed in the direction along the first axis X in a see-through manner, the first functional layer 410 covers the entire second electrode 221. That is, the four first electrodes 211, the second electrode 221, and the first functional layer 410 function as four capacitors.

As described above, the first functional layer 410 spans the third layer L3 and the fourth layer L4. In other words, the maximum dimension of the first functional layer 410 in the direction orthogonal to the first main surface 11A is larger than the maximum dimension of the first interlayer insulating layer 303 in the direction orthogonal to the first main surface 11A. In this configuration, part of the first functional layer 410 is located at the same position as the first interlayer insulating layer 303 in the direction orthogonal to the first main surface 11A. As described above, even when part of the first functional layer 410 is located in another layer and protrudes beyond the first interlayer insulating layer 303, if at least part of the first functional layer 410 is located at the same position as the first interlayer insulating layer 303 in the direction orthogonal to the first main surface 11A, the first functional layer 410 can be regarded as being located in the first interlayer insulating layer 303.

### Advantageous Effects of Second Embodiment

(2-1) In the second embodiment, the relative permittivity of the first functional layer 410 is at least twice the relative permittivity of the first interlayer insulating layer 303. With this configuration, since the relative permittivity of the first functional layer 410 is relatively high, the first functional layer 410 functions as cores of capacitors. Since the first functional layer 410 extends in a plate shape inside the first interlayer insulating layer 303, it is not necessary to increase the dimension of the first functional layer 410 greatly in the direction orthogonal to the first main surface 11A in order to assign a sufficient volume to the first functional layer 410. This configuration achieves a thin design while enabling part of the substrate 11 to function as capacitors having desired characteristics.

(2-2) The first functional layer 410 having a high relative permittivity functions as an insulator for a direct current power supply. Accordingly, wiring lines can be arranged so as to be in contact with the first functional layer 410. In the second embodiment, the first functional layer 410 is in contact with the surfaces of the second wiring layer 220 facing the directions parallel to the first main surface 11A. With this configuration, it is not necessary to arrange the first wiring layer 210 so as to intentionally avoid the first functional layer 410, and thus an increase in a dimension of the substrate 11 in directions parallel to the first main surface 11A can be suppressed.

(2-3) In the second embodiment, the first functional layer 410 is in contact with the surface of the first wiring layer 210 facing the first negative direction X2 and the surface of the second wiring layer 220 facing the first positive direction X1. With this configuration, similarly to (2-2), it is not necessary to arrange each wiring layer so as to intentionally avoid the first functional layer 410, and thus an increase in the dimension of the substrate 11 in the direction orthogonal to the first main surface 11A can be suppressed. Since the proportion of the volume of the first functional layer 410 to the space between the second electrode 221 and the first electrodes 211 can be increased, the characteristics as capacitors are improved.

(2-4) In the second embodiment, one or more semiconductor devices 100 are mounted on the first main surface 11A, and one or more semiconductor devices 100, including, in particular, a PMIC as a semiconductor switch, are mounted on the second main surface 11B. From the viewpoint of mounting the semiconductor devices 100 on both the first positive direction X1 side and the first negative direction X2 side of the semiconductor package 10, the above configuration reduces the size of the semiconductor package 10, as compared with a case where different substrates are joined together, because the semiconductor devices 100 are mounted on both main surfaces of the substrate 11.

(2-5) In the second embodiment, a PMIC is mounted as a semiconductor device 100 on the second main surface 11B. The land portion 650 for mounting a mother board is located on the second main surface 11B. With this configuration, a mother board can be coupled to the land portion 650. In a case where power is supplied by a mother board, this configuration is suitable for power control because the mother board and the PMIC are located on the same second main surface 11B side.

(2-6) In the second embodiment, the relative permittivity of the first functional layer 410 is at least twice the relative permittivity of the first interlayer insulating layer 303. That is, the first functional layer 410, the first electrodes 211, and the second electrode 221 function as capacitors. The relative permeability of the second functional layer 420 is at least twice the relative permeability of the second interlayer insulating layer 308. That is, the second functional layer 420 and the inductor wiring lines 241 function as an inductor. The second interlayer insulating layer 308 is located farther from the first main surface 11A than the first interlayer insulating layer 303. With this configuration, in a case where a mother board is coupled to the land portion 650, and current is supplied to the semiconductor package 10, the current flows from the side closer to the second main surface 11B toward the first main surface 11A. That is, with the above configuration, current is supplied in the order of the inductor, the capacitors, and the semiconductor devices 100 mounted on the first main surface 11A. This configuration suppresses an increase in wiring resistance.

(2-7) In the second embodiment, a PMIC is mounted as a semiconductor device 100 on the second main surface 11B. On the first main surface 11A, a semiconductor integrated circuit including a plurality of load circuits is mounted as a semiconductor device 100. In addition, on the first main surface 11A, a PMIC is mounted as a semiconductor device 100. Since the semiconductor package 10 includes at least two PMICs in this configuration, larger power can be supplied to the semiconductor integrated circuit.

(2-8) In the second embodiment, the substrate 11 includes, inside the substrate 11, the core portion 700 having a bending strength greater than that of the first interlayer insulating layer 303. This configuration of the substrate 11 improves an overall bending strength of the substrate 11 as compared with a configuration without the core portion 700.

(2-9) In the second embodiment, the substrate 11 does not include a layer made of the same material as the first functional layer 410 on the other of the two sides: the side closer to the first main surface 11A than the core portion 700 and the side farther from the first main surface 11A than the core portion 700. It is possible that parasitic capacitance occurs at unintended positions due to the first functional layer 410 and wiring lines located around the first functional layer 410. However, in the above configuration, since a layer corresponding to the first functional layer 410 is located only on one side with respect to the core portion 700, occurrence of parasitic capacitance at unintended positions can be suppressed.

### Modifications

The first embodiment and the second embodiment described above may be modified and implemented as described below. The first embodiment, the second embodiment, and the following modifications may be implemented in combination within a range not technically inconsistent. In the modifications illustrated in FIGS. 18 to 23 below, description of portions having configurations the same as or similar to those of the first embodiment and the second embodiment may be omitted or simplified. In FIGS. 18 to 23, portions having configurations the same as or similar to those of the first embodiment and the second embodiment may be illustrated with part of reference numerals omitted.

### Modification in FIG. 18

In the first embodiment and the second embodiment, the first functional layers 41 and 410 may be exposed at a surface of the substrate 11 in a direction parallel to the first main surface 11A. In this regard, the same applies to other functional layers.

For example, in an example illustrated in FIG. 18, a substrate 11 includes a first layer L1. The first layer L1 is the outermost layer on the first positive direction X1 side in the substrate 11. The first layer L1 includes a first interlayer insulating layer 81, a plurality of first vias 51, and a first functional layer 41. The first functional layer 41 is exposed at opposite end surfaces of the substrate 11 in directions parallel to the first main surface 11A. Specifically, the first functional layer 41 extends over the entire region of the substrate 11 in the directions orthogonal to the first positive direction X1.

In the example illustrated in FIG. 18, each first via 51 extends through the first layer L1 in the direction orthogonal to the first main surface 11A. The first interlayer insulating layer 81 is located in the portion of the first layer L1 other than the first vias 51 and the first functional layer 41. That is, in the example illustrated in FIG. 18, each first via 51 extends through the first interlayer insulating layer 81 in the direction orthogonal to the first main surface 11A. Each first via 51 also extends through the first functional layer 41 in the direction orthogonal to the first main surface 11A. The first functional layer 41 is located between portions of the first interlayer insulating layer 81 on the opposite sides in the direction orthogonal to the first main surface 11A. That is, the first functional layer 41 is located inside the first interlayer insulating layer 81.

With this configuration, when forming the first functional layer 41, it is not necessary to perform complicated processing on the shape of the first functional layer 41.

In FIG. 18, an area illustrated as a region A includes wiring layers, vias, insulating layers, and the like arranged in specified patterns. The area illustrated as the region A may include functional layers, electrodes, core portions, and other members. Detailed illustration of the region A is omitted.

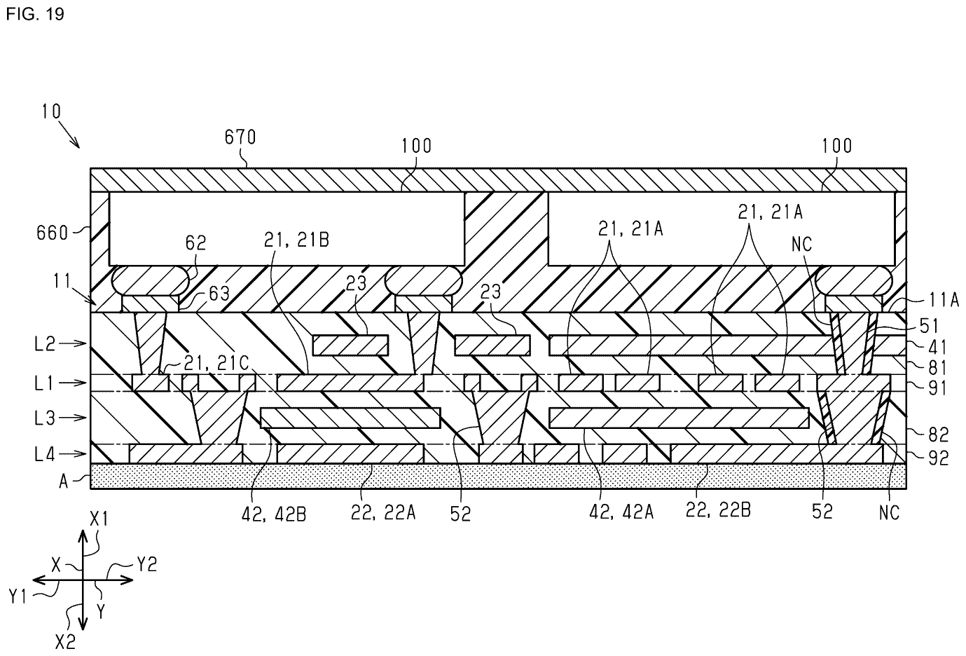

### Modification in FIG. 19

In the first embodiment and the second embodiment, peripheral surfaces of vias may be covered with another member.

In the first embodiment and the second embodiment, a wiring layer may be located at the same position as the first functional layer 41 or 410 in the direction orthogonal to the first main surface 11A. In this regard, the same applies to other functional layers.

In the first embodiment and the second embodiment, the entire region of the semiconductor devices 100, the coupling portions 62 and 630, and the outer electrodes may be covered with a resin mold.

In the first embodiment and the second embodiment, the semiconductor package 10 may further include a heat dissipation sheet.

For example, in an example illustrated in FIG. 19, a substrate 11 includes a second layer L2, a first layer L1, a third layer L3, and a fourth layer L4, which are arranged in this order from the first positive direction X1 side.

The first layer L1 includes a first wiring layer 21 and a first insulating layer 91. The first wiring layer 21 includes inductor wiring lines 21A and a first electrode 21B that are not coupled to each other within the first layer L1 in which the first wiring layer 21 is located. The first wiring layer 21 further includes other wiring lines 21C different from the inductor wiring lines 21A and the first electrode 21B. The other wiring lines 21C extend in specified patterns in the first layer L1. The first insulating layer 91 is located in the portion of the first layer L1 other than the first wiring layer 21.

The second layer L2 includes a first interlayer insulating layer 81, a plurality of first vias 51, insulating material NC, a first functional layer 41, and a third wiring layer 23. The first functional layer 41 is exposed at an end surface of the substrate 11 on the second negative direction Y2 side in a direction parallel to the first main surface 11A. The relative permeability of the first functional layer 41 is at least twice the relative permeability of the first interlayer insulating layer 81. When viewed in the direction orthogonal to the first main surface 11A in a see-through manner, the first functional layer 41 overlaps the inductor wiring lines 21A without another wiring part interposed therebetween. That is, the first functional layer 41 and the inductor wiring lines 21A function as an inductor.

Each first via 51 extends through the second layer L2 in the direction orthogonal to the first main surface 11A. At least one selected from the plurality of first vias 51 extends through the first functional layer 41 in the direction orthogonal to the first main surface 11A. The insulating material NC covers the peripheral surface of the first via 51 that extends through the first functional layer 41. The insulating material NC has a higher insulating property than the first functional layer 41. In the example illustrated in FIG. 19, the insulating material NC is an epoxy resin containing a glass filler. The material of the insulating material NC is not limited to this and may be, for example, the same as the material of the first insulating layer 31 of the first embodiment. In the example illustrated in FIG. 19, the insulating property of the first via 51 is improved due to the presence of the insulating material NC.

The third wiring layer 23 is located at the same position as the first functional layer 41 in the direction orthogonal to the first main surface 11A. In the example illustrated in FIG. 19, the material of the third wiring layer 23 is the same as the material of the first wiring layer 21 of the first embodiment. However, the material of the third wiring layer 23 is not limited to this example. Since wiring is located in the same layer as the first functional layer 41, the wiring density in the substrate 11 can be improved. That is, it is not necessary to provide wiring so as to avoid the same layer as the first functional layer 41, and an increase in the dimension of the substrate 11 in the direction orthogonal to the first main surface 11A can be suppressed.

The fourth layer L4 includes a second wiring layer 22 and a second insulating layer 92. The second wiring layer 22 includes a second electrode 22A and other wiring lines 22B different from the second electrode 22A. The second insulating layer 92 is located in the portion of the fourth layer L4 other than the second wiring layer 22.

The third layer L3 includes a second interlayer insulating layer 82, a plurality of second vias 52, a second functional layer 42, and insulating material NC. The second functional layer 42 includes a first functional portion 42A and a second functional portion 42B that are not coupled to each other within the layer in which the second functional layer 42 is located. The material of the first functional portion 42A is an organic resin containing magnetic powder. The relative permeability of the first functional portion 42A is at least twice the relative permeability of the second interlayer insulating layer 82. When viewed in the direction orthogonal to the first main surface 11A in a see-through manner, the first functional portion 42A overlaps the inductor wiring lines 21A without another wiring part interposed therebetween. That is, the first functional portion 42A and the inductor wiring lines 21A function as an inductor.

The material of the second functional portion 42B is an organic resin containing an inorganic filler. The relative permittivity of the second functional portion 42B is at least twice the relative permittivity of the second interlayer insulating layer 82. That is, the material of the first functional portion 42A is different from the material of the second functional portion 42B. When viewed in the direction orthogonal to the first main surface 11A in a see-through manner, the second functional portion 42B overlaps the first electrode 21B and the second electrode 22A without another wiring part interposed therebetween. That is, the second functional portion 42B, the first electrode 21B, and the second electrode 22A function as a capacitor. With this configuration, both an inductor and a capacitor can be disposed in the substrate 11.

Each second via 52 extends through the third layer L3. At least one selected from the plurality of second vias 52 has a peripheral surface covered with the insulating material NC. The insulating material NC is the same as that described above. In the example illustrated in FIG. 19, the first via 51 and the insulating material NC covering the peripheral surface of the first via 51 may extend through the first layer L1 and be in direct contact with the second via 52.

A plurality of semiconductor devices 100 are mounted on the first main surface 11A with outer electrodes 63 and coupling portions 62 interposed therebetween. In the example illustrated in FIG. 19, the semiconductor package 10 includes a resin mold 660 and a heat dissipation sheet 670. The resin mold 660 covers the entire peripheral surfaces of the semiconductor devices 100, the outer electrodes 63, and the coupling portions 62. Note that the surfaces of the semiconductor devices 100 on the first positive direction X1 side are not covered with the resin mold 660. The material of the resin mold 660 is, for example, an epoxy-based resin. The material of the resin mold 660 may be a polyimide-based resin, a liquid crystal polymer-based resin, an acrylic-based resin, a phenol-based resin, or a combination of some of these. The resin mold 660 may contain an inorganic filler such as a silica filler.

The heat dissipation sheet 670 covers the entire surfaces of the semiconductor devices 100 on the first positive direction X1 side. The heat dissipation sheet 670 is a resin sheet having thermal conductivity. The heat dissipation sheet 670 can efficiently absorb heat of the semiconductor devices 100 and dissipate the heat to the outside. In FIG. 19, an area illustrated as a region A includes wiring layers, vias, insulating layers, and the like arranged in specified patterns. The area illustrated as the region A may include functional layers, electrodes, core portions, and other members. Detailed illustration of the region A is omitted.

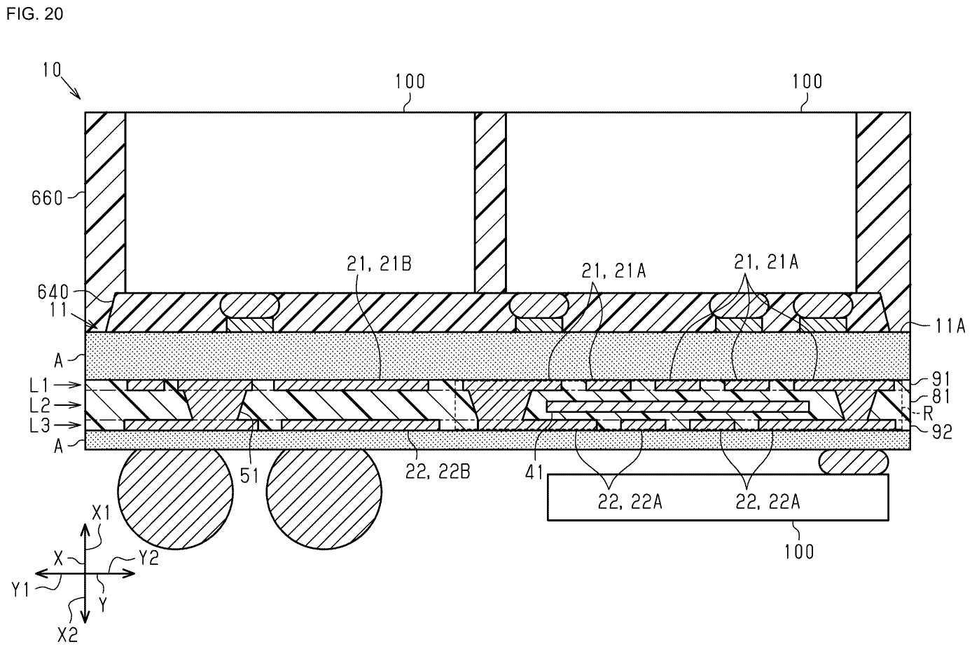

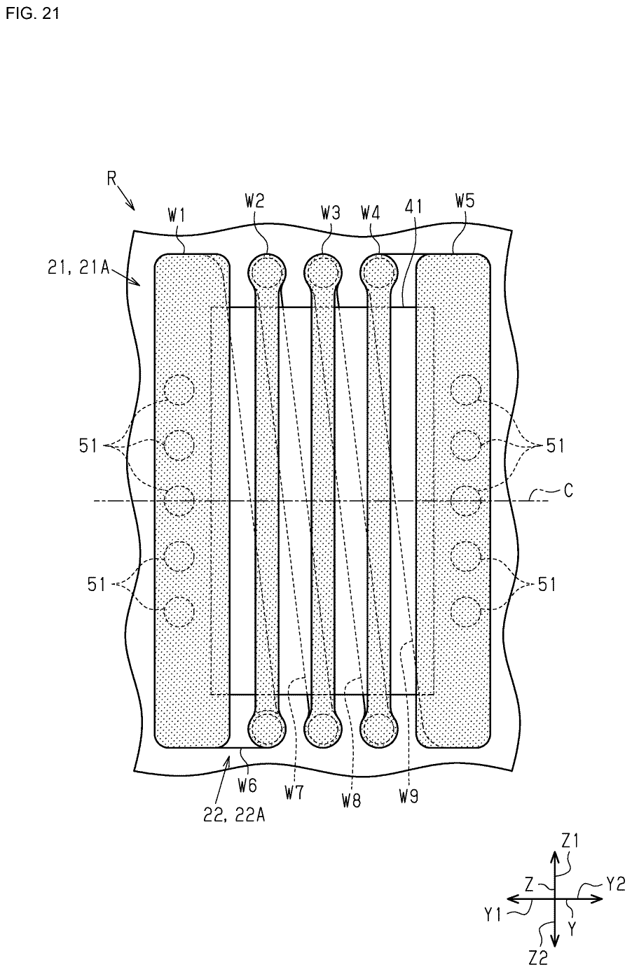

### Modification in FIGS. 20 and 21

In the first embodiment, the shapes of the first inductor wiring lines 21A and the second inductor wiring lines 22A are not limited to those in the examples of the first embodiment. In the first embodiment, the number of turns of each inductor wiring line is not limited to 0.5 turns or less.

In the first embodiment and the second embodiment, the maximum dimension of the substrate 11 in the direction orthogonal to the first main surface 11A may be the same as or larger than the maximum dimension of the semiconductor devices 100 in the direction orthogonal to the first main surface 11A.

In the second embodiment, the number of land portions 650 is not limited to that in the example of the second embodiment.

In the second embodiment, the semiconductor package 10 may further include a resin mold 660 in addition to the underfill 640.

For example, in an example illustrated in FIG. 20, a substrate 11 includes a first layer L1, a second layer L2, and a third layer L3, which are located in this order from the first positive direction X1 side.

The first layer L1 includes a first wiring layer 21 and a first insulating layer 91. The first wiring layer 21 includes first inductor wiring lines 21A as a first wiring portion. The first wiring layer 21 further includes other wiring lines 21B. The other wiring lines 21B extend in specified patterns in the first layer L1. The first insulating layer 91 is located in the portion of the first layer L1 other than the first wiring layer 21.

The second layer L2 includes a first functional layer 41, first vias 51, and a first interlayer insulating layer 81. When viewed in the direction orthogonal to the first main surface 11A in a see-through manner, the first functional layer 41 overlaps the first inductor wiring lines 21A of the first wiring layer 21 without another wiring part interposed therebetween. The relative permeability of the first functional layer 41 is at least twice the relative permeability of the first interlayer insulating layer 81. Each first via 51 extends through the second layer L2. The first interlayer insulating layer 81 is located in the portion of the second layer L2 other than the first wiring layer 21.

The third layer L3 includes a second wiring layer 22 and a second insulating layer 92. The second wiring layer 22 extends parallel to the first main surface 11A. That is, the second wiring layer 22 is located on a side of the first interlayer insulating layer 81 opposite to the first wiring layer 21. The second wiring layer 22 includes second inductor wiring lines 22A as a second wiring portion. When viewed in the direction orthogonal to the first main surface 11A in a see-through manner, the first functional layer 41 overlaps the second inductor wiring lines 22A of the second wiring layer 22 without another wiring part interposed therebetween.

The second wiring layer 22 further includes other wiring lines 22B. The other wiring lines 22B extend in specified patterns in the third layer L3. The first vias 51 extend through the first interlayer insulating layer 81 and couple the first wiring layer 21 and the second wiring layer 22. The second insulating layer 92 is located in the portion of the third layer L3 other than the second wiring layer 22.

In the example illustrated in FIG. 20, the maximum dimension of the substrate 11 in the direction orthogonal to the first main surface 11A is smaller than the maximum dimension in the direction orthogonal to the first main surface 11A of the semiconductor devices 100 mounted on the first main surface 11A. With this configuration, since the dimension of the semiconductor devices 100 in the direction orthogonal to the first main surface 11A is relatively large, the thermal resistance of the semiconductor devices 100 can be reduced. In FIG. 20, areas illustrated as regions A include wiring layers, vias, insulating layers, and the like arranged in specified patterns. The areas illustrated as the regions A may include functional layers, electrodes, core portions, and other members. Detailed illustration of the regions A is omitted.

As illustrated in FIG. 21, it is assumed that an inductor portion R surrounded by dashed lines in FIG. 20 is viewed in the direction along the first axis X in a see-through manner. FIG. 21 only illustrates the first functional layer 41, the first inductor wiring lines 21A, the second inductor wiring lines 22A, and some of the first vias 51.

The first wiring layer 21 includes five first inductor wiring lines 21A. Each first inductor wiring line 21A extends parallel to the third axis Z. The first inductor wiring lines 21A are arranged side by side in the direction along the second axis Y. The second wiring layer 22 includes four second inductor wiring lines 22A. Each second inductor wiring line 22A extends generally in the direction along the third axis Z.

The first inductor wiring lines 21A, the second inductor wiring lines 22A, and the plurality of first vias 51 are coupled in series and form an embedded inductor extending from a first end on the second positive direction Y1 side to a second end on the second negative direction Y2 side. That is, the inductor portion R functions as an embedded inductor.

In this configuration, the five first inductor wiring lines 21A are referred to, in order from the second positive direction Y1 side, as a first line W1, a second line W2, a third line W3, a fourth line W4, and a fifth line W5. The four second inductor wiring lines 22A are referred to, in order from the second positive direction Y1 side, as a sixth line W6, a seventh line W7, an eighth line W8, and a ninth line W9.

The first line W1 is coupled to the sixth line W6 with five first vias 51 interposed therebetween. The five first vias 51 are aligned in the direction along the third axis Z. An end of the sixth line W6 on the third negative direction Z2 side is coupled to an end of the second line W2 on the third negative direction Z2 side with a first via 51 interposed therebetween. An end of the second line W2 on the third positive direction Z1 side is coupled to an end of the seventh line W7 on the third positive direction Z1 side with a first via 51 interposed therebetween. An end of the seventh line W7 on the third negative direction Z2 side is coupled to an end of the third line W3 on the third negative direction Z2 side with a first via 51 interposed therebetween. An end of the third line W3 on the third positive direction Z1 side is coupled to an end of the eighth line W8 on the third positive direction Z1 side with a first via 51 interposed therebetween. An end of the eighth line W8 on the third negative direction Z2 side is coupled to an end of the fourth line W4 on the third negative direction Z2 side with a first via 51 interposed therebetween. An end of the fourth line W4 on the third positive direction Z1 side is coupled to an end of the ninth line W9 on the third positive direction Z1 side with a first via 51 interposed therebetween. The ninth line W9 is coupled to the fifth line W5 with five first vias 51 interposed therebetween.

The first functional layer 41 is surrounded by the first vias 51 described above. That is, at least part of the embedded inductor is formed by the first wiring portion, first vias 51, the second wiring portion, and first vias 51 coupled in this order and extends spirally so as to surround the first functional layer 41. In this case, the first wiring portion includes the first inductor wiring lines 21A. The second wiring portion includes the second inductor wiring lines 22A. The five first vias 51 coupled to the first line W1 are located on the second positive direction Y1 side with respect to the first functional layer 41. The five first vias 51 coupled to the fifth line W5 are located on the second negative direction Y2 side with respect to the first functional layer 41. That is, in the embedded inductor, the first vias 51 coupled at a position closest to the first end and the first vias 51 coupled at a position closest to the second end are located on opposite sides of the first functional layer 41 in the direction along a central axis C of the embedded inductor. In FIG. 21, the first inductor wiring lines 21A are indicated with dots, for convenience.

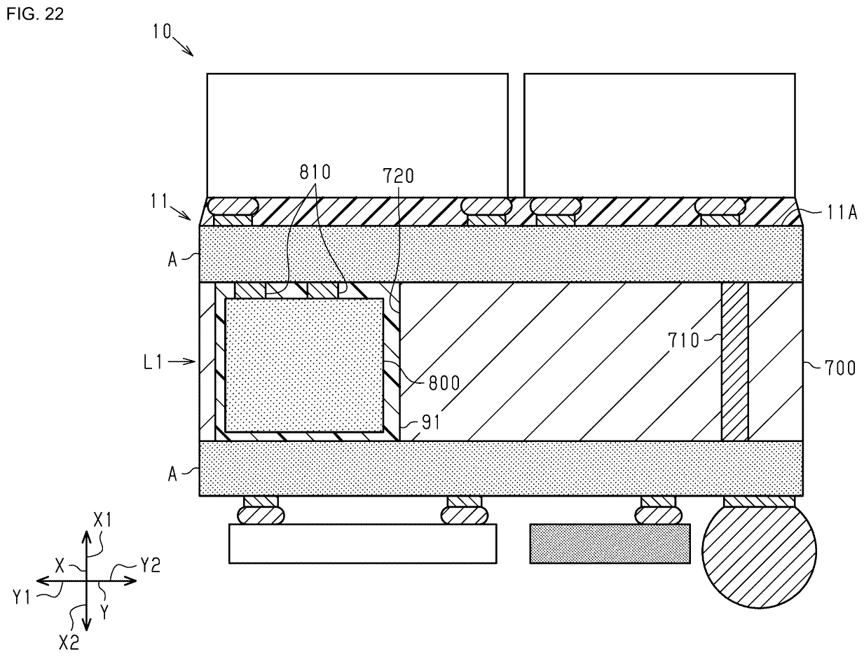

### Modification in FIG. 22

In the first embodiment and the second embodiment, the substrate 11 may include a passive component 800 therein.

For example, in an example illustrated in FIG. 22, a substrate 11 includes a first layer L1. The first layer L1 includes through wiring lines 710, a core portion 700, a passive component 800, a plurality of lead-out wiring lines 810, and a first insulating layer 91.

Each through wiring line 710 extends in a direction intersecting the first main surface 11A. Each through wiring line 710 extends through the first layer L1 in the direction orthogonal to the first main surface 11A.

The core portion 700 covers the entire peripheral surface of each through wiring line 710. That is, each through wiring line 710 extends through the core portion 700 in the direction orthogonal to the first main surface 11A. In the example illustrated in FIG. 22, the core portion 700 has a through hole 720 extending through the core portion 700 in the direction along the first axis X.

The passive component 800 is located at the same position as the core portion 700 in the direction orthogonal to the first main surface 11A. Specifically, the passive component 800 is located inside the through hole 720 of the core portion 700. The passive component 800 is not in contact with the through hole 720 in the directions parallel to the first main surface 11A. The passive component 800 is, for example, an inductor component, a capacitor component, an integrated passive device (IPD), or the like. The inductor component may include a plurality of inductors or may include only one inductor. In this regard, the same applies to the capacitor component.

Each lead-out wiring line 810 extends from the passive component 800 in the direction orthogonal to the first main surface 11A. Specifically, each lead-out wiring line 810 extends from the first positive direction X1 side of the passive component 800 toward the first positive direction X1 side. The material of the lead-out wiring lines 810 is the same as the material of the first wiring layer 21 in the first embodiment. Although not illustrated, each lead-out wiring line 810 is coupled to a via or a wiring layer adjacent to the lead-out wiring line 810 on the first positive direction X1 side. With this configuration, it is not necessary to have a wiring layer adjusted to the location of the passive component 800, and the lead-out wiring lines 810 enable the passive component 800 to be coupled to a wiring layer. That is, this configuration improves the degree of freedom in designing a wiring layer.

The first insulating layer 91 is located in the portion of the first layer L1 other than the through wiring lines 710, the core portion 700, the passive component 800, and the plurality of lead-out wiring lines 810. That is, the first insulating layer 91 fills the space inside the through hole 720 of the core portion 700 so as to surround the passive component 800 and the lead-out wiring lines 810.

The example illustrated in FIG. 22 may include a plurality of passive components 800.

In the example illustrated in FIG. 22, the relationship between the maximum dimension of the passive component 800 in the direction orthogonal to the first main surface 11A and the maximum dimension of the core portion 700 in the direction orthogonal to the first main surface 11A is not limited to the above example. However, in order to maintain the flatness of the first layer L1 during a manufacturing process, the maximum dimension of the passive component 800 in the direction orthogonal to the first main surface 11A is preferably greater than 0.7 times and less than 1.3 times (i.e., from 0.7 times to 1.3 times) the maximum dimension of the core portion 700 in the direction orthogonal to the first main surface 11A. From the viewpoint of maintaining the flatness of the first layer L1 during a manufacturing process, the difference in the dimension in the direction orthogonal to the first main surface 11A between the passive component 800 and the core portion 700 is preferably less than 10%, more preferably less than 5%.

In FIG. 22, areas illustrated as regions A include wiring layers, vias, insulating layers, and the like arranged in specified patterns. The areas illustrated as the regions A may include functional layers, electrodes, core portions, and other members. Detailed illustration of the regions A is omitted. For example, the regions A may have a configuration including a first functional layer 41, as in the substrate 11 of the first embodiment.

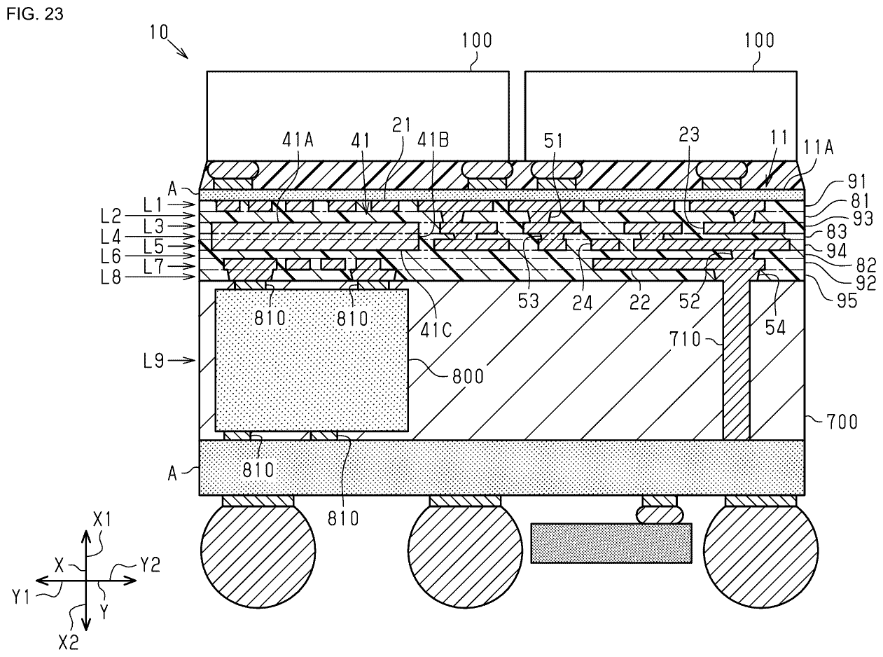

### Modification in FIG. 23

In the first embodiment and the second embodiment, the maximum dimensions of the first functional layer 41 and 410 in the direction orthogonal to the first main surface 11A may be greater than the maximum dimensions of the first wiring layers 21 and 210 in the direction orthogonal to the first main surface 11A, respectively.

In the example illustrated in FIG. 19, the substrate 11 may include, in addition to the third wiring layer 23, a wiring layer located at the same position as the first functional layer 41 at a position different from that of the third wiring layer 23 in the direction orthogonal to the first main surface 11A.

In the example illustrated in FIG. 22, the passive component 800 may be in contact with the core portion 700 in a direction parallel to the first main surface 11A.

For example, in an example illustrated in FIG. 23, a substrate 11 includes a first layer L1, a second layer L2, a third layer L3, a fourth layer L4, a fifth layer L5, a sixth layer L6, a seventh layer L7, an eighth layer L8, and a ninth layer L9, which are arranged in this order from the first positive direction X1 side.

The first layer L1 includes a first wiring layer 21 and a first insulating layer 91. The first wiring layer 21 extends in a specified pattern in the first layer L1. The first insulating layer 91 is located in the portion of the first layer L1 other than the first wiring layer 21.

The second layer L2 includes first vias 51 and a first interlayer insulating layer 81. Each first via 51 extends through the second layer L2. The first interlayer insulating layer 81 is located in the portion of the second layer L2 other than the first vias 51.

The seventh layer L7 includes a second wiring layer 22 and a second insulating layer 92. The second wiring layer 22 extends in a specified pattern in the seventh layer L7. The second insulating layer 92 is located in the portion of the seventh layer L7 other than the second wiring layer 22.

The sixth layer L6 includes second vias 52 and a second interlayer insulating layer 82. Each second via 52 extends through the second layer L2. The second interlayer insulating layer 82 is located in the portion of the sixth layer L6 other than the second vias 52.

The third layer L3 includes a first functional portion 41A that is part of a first functional layer 41, a third wiring layer 23, and a third insulating layer 93. When viewed in the direction orthogonal to the first main surface 11A in a see-through manner, the first functional portion 41A overlaps the first wiring layer 21 without another wiring part interposed therebetween.

The third wiring layer 23 extends parallel to the first main surface 11A. That is, the third wiring layer 23 is a wiring layer located at a position different from that of the first wiring layer 21 in the direction orthogonal to the first main surface 11A. The third wiring layer 23 is located at the same position as the first functional portion 41A of the first functional layer 41 in the direction orthogonal to the first main surface 11A. The maximum dimension of the third wiring layer 23 in the direction orthogonal to the first main surface 11A is the same as the maximum dimension of the first wiring layer 21 in the direction orthogonal to the first main surface 11A. The third insulating layer 93 is located in the portion of the third layer L3 other than the third wiring layer 23.

The fourth layer L4 includes a second functional portion 41B that is part of the first functional layer 41, third vias 53, and a third interlayer insulating layer 83. The second functional portion 41B is coupled to the first functional portion 41A on the first negative direction X2 side. Each third via 53 extends through the fourth layer L4. The third interlayer insulating layer 83 is located in the portion of the fourth layer L4 other than the third vias 53. When part of the first functional layer 41 is in the third interlayer insulating layer 83 as in the example illustrated in FIG. 23, the first functional layer 41 can be regarded as “extending in the interlayer insulating layer.”

The fifth layer L5 includes a third functional portion 41C that is part of the first functional layer 41, a fourth wiring layer 24, and a fourth insulating layer 94. The third functional portion 41C is coupled to the second functional portion 41B on the first negative direction X2 side. That is, when viewed in the direction orthogonal to the first main surface 11A in a see-through manner, the first functional layer 41 including the first functional portion 41A to the third functional portion 41C overlaps the first wiring layer 21 without another wiring part interposed therebetween. The relative permeability of the first functional layer 41 is at least twice the relative permeability of the first interlayer insulating layer 81.

The fourth wiring layer 24 extends parallel to the first main surface 11A. That is, the fourth wiring layer 24 is a wiring layer located at a position different from that of the first wiring layer 21 in the direction orthogonal to the first main surface 11A. The fourth wiring layer 24 is located at the same position as the third functional portion 41C of the first functional layer 41 in the direction orthogonal to the first main surface 11A. The maximum dimension of the fourth wiring layer 24 in the direction orthogonal to the first main surface 11A is the same as the maximum dimension of the first wiring layer 21 in the direction orthogonal to the first main surface 11A. The fourth insulating layer 94 is located in the portion of the fifth layer L5 other than the fourth wiring layer 24. Thus, the first functional layer 41 spans the third layer L3, the fourth layer L4, and the fifth layer L5. In other words, the maximum dimension of the first functional layer 41 in the direction orthogonal to the first main surface 11A is the same as the combined maximum dimension of the third wiring layer 23, the fourth wiring layer 24, and the third vias 53 in the direction orthogonal to the first main surface 11A. In other words, the maximum dimension of the first functional layer 41 in the direction orthogonal to the first main surface 11A is the same as the value obtained by summing twice the maximum dimension of the third wiring layer 23 in the direction orthogonal to the first main surface 11A and one time the maximum dimension of the third interlayer insulating layer 83 in the direction orthogonal to the first main surface 11A. That is, the maximum dimension of the first functional layer 41 in the direction orthogonal to the first main surface 11A is at least twice the maximum dimension of the first wiring layer 21 in the direction orthogonal to the first main surface 11A. As in the example illustrated in FIG. 23, when the maximum dimension of the first functional layer 41 in the direction orthogonal to the first main surface 11A is the same as the value obtained by summing an integer multiple of the maximum dimension of the third wiring layer 23 in the direction orthogonal to the first main surface 11A and an integer multiple of the maximum dimension of the third interlayer insulating layer 83 in the direction orthogonal to the first main surface 11A, the first functional layer 41 can be formed together with an insulating layer in the same layer as a wiring layer and an interlayer insulating layer. In other words, since the insulating layers are formed corresponding to the thickness of the first functional layer 41, significant deterioration of flatness, such as a case where only the first functional layer 41 protrudes during a manufacturing process, does not occur.

The eighth layer L8 includes fourth vias 54 and a fifth insulating layer 95. Each fourth via 54 extends through the eighth layer L8. The fifth insulating layer 95 is located in the portion of the eighth layer L8 other than the fourth vias 54.

The ninth layer L9 includes a through wiring line 710, a core portion 700, a passive component 800, and a plurality of lead-out wiring lines 810. The through wiring line 710 extends in a direction intersecting the first main surface 11A. The through wiring line 710 extends through the ninth layer L9 in the direction orthogonal to the first main surface 11A.

The passive component 800 is located at the same position as the through wiring line 710 in the direction orthogonal to the first main surface 11A. Some of the lead-out wiring lines 810 extend from the first positive direction X1 side of the passive component 800 toward the first positive direction X1 side. Others of the lead-out wiring lines 810 extend from the first negative direction X2 side of the passive component 800 toward the first negative direction X2 side.

The core portion 700 is located in the portion of the ninth layer L9 other than the through wiring line 710, the passive component 800, and the lead-out wiring lines 810. That is, the through wiring line 710 extends through the core portion 700 in the direction orthogonal to the first main surface 11A. The passive component 800 is in contact with the core portion 700 in directions parallel to the first main surface 11A.

In FIG. 23, areas illustrated as regions A include wiring layers, vias, insulating layers, and the like arranged in specified patterns. The areas illustrated as the regions A may include functional layers, electrodes, core portions, and other members. Detailed illustration of the regions A is omitted.

### Other Modifications

In the first embodiment and the second embodiment, the number of semiconductor devices 100 mounted on the first main surface 11A is not limited. Similarly, the number of semiconductor devices 100 mounted on the second main surface 11B is not limited. The types of the semiconductor devices 100 mounted on each main surface are not limited.

In the first embodiment and the second embodiment, at least the volume of the first functional layer 41 or 410 may be 0.5 times or less the volume of the substrate 11. In this regard, the same applies to the second functional layers 42 and 420. That is, the sum of the volume of the second functional layer 42 and the volume of the first functional layer 41 and the sum of the volume of the second functional layer 420 and the volume of the first functional layer 410 may each be greater than 0.5 times the volume of the substrate 11. If the volume of each functional layer is sufficiently smaller than the volume of the substrate 11, the advantageous effect described in (1-6) can be achieved.

In the first embodiment, the substrate 11 needs only to include at least the first wiring layer 21, the first interlayer insulating layer 32, and the first functional layer 41 having a relative permeability of at least twice that of the first interlayer insulating layer 32. Other wiring parts, insulating layers, vias, electrodes, and the like may be modified as appropriate.

In the first embodiment, the maximum dimension of the first functional layer 41 in the direction orthogonal to the first main surface 11A may be different from the maximum dimension of the second functional layer 42 in the direction orthogonal to the first main surface 11A.

In the first embodiment, the relative permeability of the first functional layer 41 may be less than 5. In this regard, the same applies to the second functional layer 420 of the second embodiment.

In the first embodiment, the material of the first functional layer 41 may have magnetic anisotropy. The first imaginary straight lines V1 and the second imaginary straight lines V2 may extend in parallel. In other words, the first inductor wiring lines 21A and the second inductor wiring lines 21B may extend in parallel.

In the second embodiment, the substrate 11 needs only to include at least the first wiring layer 210, the second wiring layer 220, the first interlayer insulating layer 303 located between the first wiring layer 210 and the second wiring layer 220, and the first functional layer 410 having a relative permittivity of at least twice that of the first interlayer insulating layer 303. In the second embodiment, the number of first electrodes 211 needs only to be at least one.

In the second embodiment, the first functional layer 410 may further be in contact with surfaces of the first electrodes 211 that face in a direction parallel to the first main surface 11A. The second embodiment may have a configuration in which the first functional layer 410 is not in contact with the surfaces of either the first electrodes 211 or the second electrode 221 that face in the directions parallel to the first main surface 11A.

The second embodiment may have a configuration in which the first functional layer 410 is not in contact with any of the surfaces of the first electrode 211 and the second electrode 221 that are orthogonal to the first main surface 11A. Alternatively, the first functional layer 410 may be in contact with a surface of either the first electrodes 211 or the second electrode 221, the surface being orthogonal to the first main surface 11A.

In the second embodiment, the semiconductor package 10 may have a configuration without the land portion 650.

In the second embodiment, the second interlayer insulating layer 308 may be located on the side closer to the first main surface 11A than the first interlayer insulating layer 303. That is, when current flows from the second main surface 11B side, the current may flow in the order of the capacitors and the inductor.

In the second embodiment, the maximum dimension of the core portion 700 in the direction along the first axis X may be smaller than the maximum dimension of the first interlayer insulating layer 303 in the direction along the first axis X. In this case, the material of the core portion 700 is preferably selected such that the bending strength of the core portion 700 is greater than that of the first interlayer insulating layer 303. However, the bending strength of the core portion 700 may be smaller than the bending strength of the first interlayer insulating layer 303.

In the second embodiment, the substrate 11 may have a configuration without the through wiring lines 710. The substrate 11 may function such that the first main surface 11A side and the second main surface 11B side with respect to the through wiring lines 710, in other words, the core portion 700, are different components.

In the second embodiment, the substrate 11 may include a layer made of the same material as the first functional layer 410 on the side farther from the first main surface 11A than the core portion 700. Similarly, the substrate 11 may include a layer made of the same material as the second functional layer 420 on the side closer to the first main surface 11A than the core portion 700.

### Appendices

The following describes technical ideas derivable from the embodiments and modifications described above.
[1] A semiconductor package including a substrate having a first main surface; and a semiconductor device mounted on the first main surface, in which the substrate includes a first wiring layer extending parallel to the first main surface, a first interlayer insulating layer located at a position different from a position of the first wiring layer in a direction orthogonal to the first main surface, and a first functional layer having a plate shape, located inside the first interlayer insulating layer, and extending parallel to the first main surface. When viewed in the direction orthogonal to the first main surface in a see-through manner, the first functional layer overlaps the first wiring layer without another wiring part interposed therebetween. A volume of the first functional layer is 0.5 times or less a volume of the substrate, and a relative permeability of the first functional layer is at least twice a relative permeability of the first interlayer insulating layer.
[2] The semiconductor package according to [1], in which the first wiring layer includes a first inductor wiring line, the number of turns of the first inductor wiring line is 0.5 turns or less, and the relative permeability of the first functional layer is 5 or more.
[3] The semiconductor package according to [1] or [2], in which the first wiring layer includes a first inductor wiring line and a second inductor wiring line that are not coupled to each other within a layer in which the first wiring layer is located, the number of turns of the first inductor wiring line is 0.5 turns or less, the number of turns of the second inductor wiring line is 0.5 turns or less, and a material of the first functional layer does not have magnetic anisotropy. When a first imaginary straight line passing through a first line end and a second line end of the first inductor wiring line and a second imaginary straight line passing through a first line end and a second line end of the second inductor wiring line are assumed, the first imaginary straight line and the second imaginary straight line intersect each other.
[4] The semiconductor package according to [1], in which the substrate includes a second wiring layer located on a side of the first interlayer insulating layer opposite to the first wiring layer and extending parallel to the first main surface, and a plurality of vias extending through the first interlayer insulating layer and coupling the first wiring layer and the second wiring layer to each other. The first wiring layer includes a first wiring portion, the second wiring layer includes a second wiring portion, the first wiring portion, the second wiring portion, and the plurality of vias are coupled in series and form an embedded inductor extending from a first end to a second end. At least part of the embedded inductor is formed by the first wiring portion, some of the vias, the second wiring portion, and others of the vias coupled in this order and extends spirally so as to surround the first functional layer. One of the vias that is coupled at a position closest to the first end and one of the vias that is coupled at a position closest to the second end are located on opposite sides of the first functional layer in a direction along a central axis of the embedded inductor.
[5] A semiconductor package including a substrate having a first main surface; and a semiconductor device mounted on the first main surface. The substrate includes a first wiring layer extending parallel to the first main surface, a second wiring layer located at a position different from a position of the first wiring layer in a direction orthogonal to the first main surface and extending parallel to the first main surface, a first interlayer insulating layer located between the first wiring layer and the second wiring layer, and a first functional layer having a plate shape, located inside the first interlayer insulating layer, and extending parallel to the first main surface. When viewed in the direction orthogonal to the first main surface in a see-through manner, the first functional layer overlaps the first wiring layer and the second wiring layer without another wiring part interposed therebetween. A volume of the first functional layer is 0.5 times or less a volume of the substrate, and a relative permittivity of the first functional layer is at least twice a relative permittivity of the first interlayer insulating layer.
[6] The semiconductor package according to [5], in which the first functional layer is in contact with at least one selected from surfaces of the first wiring layer facing directions parallel to the first main surface and surfaces of the second wiring layer facing directions parallel to the first main surface.
[7] The semiconductor package according to [5] or [6], in which the first functional layer is in contact with at least one selected from surfaces of the first wiring layer facing directions orthogonal to the first main surface and surfaces of the second wiring layer facing directions orthogonal to the first main surface.
[8] The semiconductor package according to any one of [1] to [7], in which the substrate further includes a second interlayer insulating layer located at a position different from a position of the first interlayer insulating layer in the direction orthogonal to the first main surface, and a second functional layer having a plate shape, located inside the second interlayer insulating layer, and extending parallel to the first main surface. A sum of a volume of the second functional layer and the volume of the first functional layer is 0.5 times or less the volume of the substrate, and a material of the second functional layer is the same as a material of the first functional layer.
[9] The semiconductor package according to any one of [1] to [8], in which the substrate further includes a second interlayer insulating layer located at a position different from a position of the first interlayer insulating layer in the direction orthogonal to the first main surface, and a second functional layer having a plate shape, located inside the second interlayer insulating layer, and extending parallel to the first main surface. A maximum dimension of the second functional layer in the direction orthogonal to the first main surface is the same as a maximum dimension of the first functional layer in the direction orthogonal to the first main surface.
[10] The semiconductor package according to any one of [1] to [9], in which the substrate includes a plurality of vias extending through the first interlayer insulating layer in the direction orthogonal to the first main surface, and at least one selected from the plurality of vias extends through the first functional layer in the direction orthogonal to the first main surface.
[11] The semiconductor package according to [10], in which the substrate includes insulating material having a higher insulating property than the first functional layer and covering a peripheral surface of the via that extends through the first functional layer.
[12] The semiconductor package according to any one of [1] to [11], in which the substrate further includes a third wiring layer located at a position different from the position of the first wiring layer in the direction orthogonal to the first main surface and extending parallel to the first main surface, and the third wiring layer is located at the same position as the first functional layer in the direction orthogonal to the first main surface.
[13] The semiconductor package according to [12], in which a maximum dimension of the first functional layer in the direction orthogonal to the first main surface is larger than a maximum dimension of the first interlayer insulating layer in the direction orthogonal to the first main surface. The maximum dimension of the first functional layer in the direction orthogonal to the first main surface is equal to a value obtained by summing an integer multiple of a maximum dimension of the third wiring layer in the direction orthogonal to the first main surface and an integer multiple of the maximum dimension of the first interlayer insulating layer in the direction orthogonal to the first main surface.
[14] The semiconductor package according to any one of [1] to [13], in which the first functional layer includes a first functional portion and a second functional portion that are not coupled to each other within a layer in which the first functional layer is located, and a material of the first functional portion is different from a material of the second functional portion.
[15] The semiconductor package according to any one of [1] to [14], in which a maximum dimension of the substrate in the direction orthogonal to the first main surface is smaller than a maximum dimension of the semiconductor device in the direction orthogonal to the first main surface.
[16] The semiconductor package according to any one of [1] to [15], in which the substrate further has a second main surface parallel to the first main surface, and the substrate further includes one or more semiconductor devices mounted on the second main surface, the semiconductor devices including a semiconductor switch, and a land portion for coupling a mother board that is mounted on the second main surface.
[17] The semiconductor package according to [16], in which the number of the semiconductor devices mounted on the first main surface is two or more, at least one selected from the semiconductor devices mounted on the first main surface is a semiconductor integrated circuit including a plurality of load circuits, and at least one selected from the semiconductor devices mounted on the first main surface is a semiconductor switch.
[18] The semiconductor package according to any one of [5] to [17], in which the substrate further has a second main surface parallel to the first main surface, the substrate further includes a second interlayer insulating layer located at a position different from a position of the first interlayer insulating layer in the direction orthogonal to the first main surface, a second functional layer having a plate shape, located inside the second interlayer insulating layer, and extending parallel to the first main surface, one or more semiconductor devices mounted on the second main surface, the semiconductor devices including a semiconductor switch, and a land portion for coupling a mother board that is mounted on the second main surface. The second interlayer insulating layer is located on a side farther from the first main surface than the first interlayer insulating layer. A relative permittivity of the first functional layer is at least twice a relative permittivity of the first interlayer insulating layer, and a relative permeability of the second functional layer is at least twice a relative permeability of the second interlayer insulating layer.
[19] The semiconductor package according to any one of [1] to [18], in which the substrate includes, inside the substrate, a core portion having a bending strength greater than a bending strength of the first interlayer insulating layer.
[20] The semiconductor package according to [19], in which the substrate further includes a second wiring layer located at a position different from the position of the first wiring layer in the direction orthogonal to the first main surface and extending parallel to the first main surface. The first wiring layer and the second wiring layer are located on opposite sides of the core portion in the direction orthogonal to the first main surface, and the substrate further includes a through wiring line extending through the core portion in the direction orthogonal to the first main surface and coupling the first wiring layer and the second wiring layer to each other.
[21] The semiconductor package according to [19] or [20], in which the first functional layer is located on only one of two sides which are a side closer to the first main surface than the core portion and a side farther from the first main surface than the core portion in the direction orthogonal to the first main surface. The substrate does not include a layer made of the same material as the first functional layer on the other of the two sides: the side closer to the first main surface than the core portion and the side farther from the first main surface than the core portion.
[22] The semiconductor package according to any one of [19] to [21], in which the substrate further includes a passive component located at the same position as the core portion in the direction orthogonal to the first main surface, and a maximum dimension of the passive component in the direction orthogonal to the first main surface is greater than 0.7 times and less than 1.3 times (i.e., from 0.7 times to 1.3 times) a maximum dimension of the core portion in the direction orthogonal to the first main surface.
[23] The semiconductor package according to any one of [19] to [22], in which the substrate further includes a passive component located at the same position as the core portion in the direction orthogonal to the first main surface, and the passive component is in contact with the core portion in a direction parallel to the first main surface.

What is claimed is:

1. A semiconductor package comprising:
a substrate having a first main surface; and
a semiconductor device mounted on the first main surface, wherein
the substrate includes
a first wiring layer extending parallel to the first main surface,
a first interlayer insulating layer at a position different from a position of the first wiring layer in a direction orthogonal to the first main surface, and
a first functional layer having a plate shape, being inside the first interlayer insulating layer, and extending parallel to the first main surface,
when viewed in the direction orthogonal to the first main surface in a see-through manner, the first functional layer overlaps the first wiring layer without another wiring part interposed therebetween,
a volume of the first functional layer is 0.5 times or less a volume of the substrate, and
a relative permeability of the first functional layer is at least twice a relative permeability of the first interlayer insulating layer.

2. The semiconductor package according to claim 1, wherein
the first wiring layer includes a first inductor wiring line,
a number of turns of the first inductor wiring line is 0.5 turns or less, and
the relative permeability of the first functional layer is 5 or more.

3. The semiconductor package according to claim 1, wherein
the first wiring layer includes a first inductor wiring line and a second inductor wiring line that are not coupled to each other within a layer in which the first wiring layer is located,
a number of turns of the first inductor wiring line is 0.5 turns or less,
a number of turns of the second inductor wiring line is 0.5 turns or less,
a material of the first functional layer does not have magnetic anisotropy, and
when a first imaginary straight line passing through a first line end and a second line end of the first inductor wiring line and a second imaginary straight line passing through a first line end and a second line end of the second inductor wiring line are assumed, the first imaginary straight line and the second imaginary straight line intersect each other.

4. The semiconductor package according to claim 1, wherein
the substrate includes
a second wiring layer on a side of the first interlayer insulating layer opposite to the first wiring layer and extending parallel to the first main surface, and
a plurality of vias extending through the first interlayer insulating layer and coupling the first wiring layer and the second wiring layer to each other,
the first wiring layer includes a first wiring portion,
the second wiring layer includes a second wiring portion,
the first wiring portion, the second wiring portion, and the plurality of vias are coupled in series and configure an embedded inductor extending from a first end to a second end,
at least part of the embedded inductor is configured by the first wiring portion, some of the vias, the second wiring portion, and others of the vias coupled in this order and extends spirally so as to surround the first functional layer, and
one of the vias that is coupled at a position closest to the first end and one of the vias that is coupled at a position closest to the second end are on opposite sides of the first functional layer in a direction along a central axis of the embedded inductor.

5. A semiconductor package comprising:
a substrate having a first main surface; and
a semiconductor device mounted on the first main surface, wherein
the substrate includes
a first wiring layer extending parallel to the first main surface,
a second wiring layer at a position different from a position of the first wiring layer in a direction orthogonal to the first main surface and extending parallel to the first main surface,
a first interlayer insulating layer between the first wiring layer and the second wiring layer, and
a first functional layer having a plate shape, being inside the first interlayer insulating layer, and extending parallel to the first main surface,
when viewed in the direction orthogonal to the first main surface in a see-through manner, the first functional layer overlaps the first wiring layer and the second wiring layer without another wiring part interposed therebetween,
a volume of the first functional layer is 0.5 times or less a volume of the substrate, and
a relative permittivity of the first functional layer is at least twice a relative permittivity of the first interlayer insulating layer.

6. The semiconductor package according to claim 5, wherein
the first functional layer is in contact with at least one selected from surfaces of the first wiring layer facing directions parallel to the first main surface and surfaces of the second wiring layer facing directions parallel to the first main surface.

7. The semiconductor package according to claim 5, wherein
the first functional layer is in contact with at least one selected from surfaces of the first wiring layer facing directions orthogonal to the first main surface and surfaces of the second wiring layer facing directions orthogonal to the first main surface.

8. The semiconductor package according to claim 1, wherein
the substrate further includes
a second interlayer insulating layer at a position different from a position of the first interlayer insulating layer in the direction orthogonal to the first main surface, and
a second functional layer having a plate shape, being inside the second interlayer insulating layer, and extending parallel to the first main surface,
a sum of a volume of the second functional layer and the volume of the first functional layer is 0.5 times or less the volume of the substrate, and
a material of the second functional layer is the same as a material of the first functional layer.

9. The semiconductor package according to claim 1, wherein
the substrate further includes
a second interlayer insulating layer at a position different from a position of the first interlayer insulating layer in the direction orthogonal to the first main surface, and
a second functional layer having a plate shape, being inside the second interlayer insulating layer, and extending parallel to the first main surface, and
a maximum dimension of the second functional layer in the direction orthogonal to the first main surface is the same as a maximum dimension of the first functional layer in the direction orthogonal to the first main surface.

10. The semiconductor package according to claim 1, wherein
the substrate includes a plurality of vias extending through the first interlayer insulating layer in the direction orthogonal to the first main surface, and
at least one selected from the plurality of vias extends through the first functional layer in the direction orthogonal to the first main surface.

11. The semiconductor package according to claim 10, wherein
the substrate includes insulating material having a higher insulating property than the first functional layer and covering a peripheral surface of the via that extends through the first functional layer.

12. The semiconductor package according to claim 1, wherein
the substrate further includes a third wiring layer at a position different from the position of the first wiring layer in the direction orthogonal to the first main surface and extending parallel to the first main surface, and
the third wiring layer is at the same position as the first functional layer in the direction orthogonal to the first main surface.

13. The semiconductor package according to claim 12, wherein
a maximum dimension of the first functional layer in the direction orthogonal to the first main surface is larger than a maximum dimension of the first interlayer insulating layer in the direction orthogonal to the first main surface, and
the maximum dimension of the first functional layer in the direction orthogonal to the first main surface is equal to a value obtained by summing an integer multiple of a maximum dimension of the third wiring layer in the direction orthogonal to the first main surface and an integer multiple of the maximum dimension of the first interlayer insulating layer in the direction orthogonal to the first main surface.

14. The semiconductor package according to claim 1, wherein
the first functional layer includes a first functional portion and a second functional portion that are not coupled to each other within a layer in which the first functional layer is located, and
a material of the first functional portion is different from a material of the second functional portion.

15. The semiconductor package according to claim 1, wherein
a maximum dimension of the substrate in the direction orthogonal to the first main surface is smaller than a maximum dimension of the semiconductor device in the direction orthogonal to the first main surface.

16. The semiconductor package according to claim 1, wherein
the substrate further has a second main surface parallel to the first main surface, and
the substrate further includes
one or more semiconductor devices mounted on the second main surface, the semiconductor devices including a semiconductor switch, and
a land portion for coupling a mother board that is mounted on the second main surface.

17. The semiconductor package according to claim 16, wherein
a number of the semiconductor devices mounted on the first main surface is two or more,
at least one selected from the semiconductor devices mounted on the first main surface is a semiconductor integrated circuit including a plurality of load circuits, and
at least one selected from the semiconductor devices mounted on the first main surface is a semiconductor switch.

18. The semiconductor package according to claim 5, wherein
the substrate further has a second main surface parallel to the first main surface,
the substrate further includes
a second interlayer insulating layer at a position different from a position of the first interlayer insulating layer in the direction orthogonal to the first main surface,
a second functional layer having a plate shape, being inside the second interlayer insulating layer, and extending parallel to the first main surface,
one or more semiconductor devices mounted on the second main surface, the semiconductor devices including a semiconductor switch, and
a land portion for coupling a mother board that is mounted on the second main surface,
the second interlayer insulating layer is on a side farther from the first main surface than the first interlayer insulating layer,
a relative permittivity of the first functional layer is at least twice a relative permittivity of the first interlayer insulating layer, and
a relative permeability of the second functional layer is at least twice a relative permeability of the second interlayer insulating layer.

19. The semiconductor package according to claim 1, wherein
the substrate includes, inside the substrate, a core portion having a bending strength greater than a bending strength of the first interlayer insulating layer.

20. The semiconductor package according to claim 19, wherein
the substrate further includes a second wiring layer at a position different from the position of the first wiring layer in the direction orthogonal to the first main surface and extending parallel to the first main surface,
the first wiring layer and the second wiring layer are on opposite sides of the core portion in the direction orthogonal to the first main surface, and
the substrate further includes a through wiring line extending through the core portion in the direction orthogonal to the first main surface and coupling the first wiring layer and the second wiring layer to each other.

21. The semiconductor package according to claim 19, wherein
the first functional layer is on only one of two sides which are a side closer to the first main surface than the core portion and a side farther from the first main surface than the core portion in the direction orthogonal to the first main surface, and
the substrate does not include a layer made of the same material as the first functional layer on the other of the two sides which re the side closer to the first main surface than the core portion and the side farther from the first main surface than the core portion.

22. The semiconductor package according to claim 19, wherein
the substrate further includes a passive component at the same position as the core portion in the direction orthogonal to the first main surface, and
a maximum dimension of the passive component in the direction orthogonal to the first main surface is from 0.7 times to 1.3 times a maximum dimension of the core portion in the direction orthogonal to the first main surface.

23. The semiconductor package according to claim 19, wherein
the substrate further includes a passive component at the same position as the core portion in the direction orthogonal to the first main surface, and
the passive component is in contact with the core portion in a direction parallel to the first main surface.
